(19) United States
(12) Patent Application Publication
(10) Pub. No.: US 2026/0075953 A1
(43) Pub. Date: Mar. 12, 2026

(54) STACKED SUBSTRATE AND METHOD OF MANUFACTURING SEMICONDUCTOR DEVICE

(71) Applicant: Kioxia Corporation, Tokyo (JP)

(72) Inventors: Yoshio MIZUTA, Yokkaichi Mie (JP); Hidekazu HAYASHI, Yokkaichi Mie (JP)

(73) Assignee: Kioxia Corporation, Tokyo (JP)

(21) Appl. No.: 19/070,173

(22) Filed: Mar. 4, 2025

(30) Foreign Application Priority Data
Sep. 12, 2024 (JP) 2024-158074

(51) Int. Cl. H10D 88/00; H01L 21/762; H01L 23/373

(52) U.S. Cl. CPC H10D 88/01; H10P 90/1916; H10W 10/181; H10W 40/253

(57) ABSTRACT

A stacked substrate of an embodiment is a stacked substrate for separating a semiconductor substrate using thermal expansion by a laser beam, the stacked substrate including the semiconductor substrate, a first insulating layer disposed above the semiconductor substrate, and a polysilicon layer that is disposed in contact with the first insulating layer, a thickness of the polysilicon layer being larger than a thickness of the first insulating layer in a direction perpendicular to a surface of the semiconductor substrate, and the polysilicon layer being doped with phosphorus.

### CROSS-REFERENCE TO RELATED APPLICATIONS

This application is based upon and claims the benefit of priority from Japanese Patent Application No. 2024-158074, filed on Sep. 12, 2024; the entire contents of which are incorporated herein by reference.

### FIELD

Embodiments described herein relate generally to a stacked substrate and a method of manufacturing a semiconductor device.

### BACKGROUND

In some cases, a semiconductor device such as a three-dimensional nonvolatile memory is manufactured by bonding a support substrate on which a plurality of memory pillars are formed and a semiconductor substrate on which a peripheral circuit is formed. After bonding with the semiconductor substrate, the support substrate is separated and reused.

An insulating layer or the like for protecting the support substrate is formed on the support substrate, and the support substrate on the insulating layer side is thermally expanded by irradiation with a laser beam or the like. As a result, the support substrate and the insulating layer are cleaved, and the support substrate can be separated. At this time, damage such as lattice defects may occur in the support substrate.

### BRIEF DESCRIPTION OF THE DRAWINGS

FIG. 1 is a cross-sectional view illustrating a configuration example of a semiconductor device according to an embodiment;

FIGS. 2A to 2D are cross-sectional views sequentially illustrating a part of a procedure of a method of manufacturing the semiconductor device according to the embodiment;

FIGS. 3A and 3B are diagrams sequentially illustrating a part of the procedure of the method of manufacturing the semiconductor device according to the embodiment;

FIG. 4 is a diagram sequentially illustrating a part of the procedure of the method of manufacturing the semiconductor device according to the embodiment;

FIGS. 5A to 5C are diagrams sequentially illustrating a part of the procedure of the method of manufacturing the semiconductor device according to the embodiment;

FIGS. 6A to 6E are diagrams sequentially illustrating a part of the procedure of the method of manufacturing the semiconductor device according to the embodiment;

FIG. 7 is a diagram sequentially illustrating a part of the procedure of the method of manufacturing the semiconductor device according to the embodiment;

FIGS. 8A to 8E are diagrams sequentially illustrating a part of the procedure of the method of manufacturing the semiconductor device according to the embodiment;

FIGS. 9A to 9C are cross-sectional views illustrating a part of a procedure of a regeneration process of a support substrate according to the embodiment;

FIGS. 10A to 10E are schematic cross-sectional views illustrating a state of separating of a support substrate according to a comparative example;

FIGS. 11A to 11E are schematic cross-sectional views illustrating a state of separating of the support substrate according to the comparative example;

FIG. 12 is a cross-sectional view illustrating an example of a configuration of a support substrate according to a first modification of the embodiment;

FIG. 13 is a cross-sectional view illustrating an example of a configuration of a support substrate according to a second modification of the embodiment;

FIGS. 14A and 14B are schematic cross-sectional views illustrating a state of separating of the support substrate according to the second modification of the embodiment;

FIGS. 15A and 15B are schematic cross-sectional views illustrating a state of separating of the support substrate according to the second modification of the embodiment;

FIG. 16 is a cross-sectional view illustrating an example of a configuration of a support substrate according to a third modification of the embodiment;

FIGS. 17A and 17B are schematic cross-sectional views illustrating a state of separating of the support substrate according to the third modification of the embodiment;

FIGS. 18A and 18B are schematic cross-sectional views illustrating a state of separating of the support substrate according to the third modification of the embodiment;

FIG. 19 is a cross-sectional view illustrating an example of a configuration of a support substrate according to a fourth modification of the embodiment;

FIGS. 20A and 20B are schematic cross-sectional views illustrating a state of separating of the support substrate according to the fourth modification of the embodiment;

FIGS. 21A and 21B are schematic cross-sectional views illustrating a state of separating of the support substrate according to the fourth modification of the embodiment;

FIG. 22 is a schematic diagram illustrating a measurement substrate according to an example and a method of measuring absorptivity;

FIG. 23 is a schematic diagram illustrating a method of calculating the absorptivity of a polysilicon layer included in the measurement substrate according to the example;

FIG. 24 is a schematic diagram illustrating a method of calculating the absorptivity of the polysilicon layer included in the measurement substrate according to the example; and

FIG. 25 is a graph showing the absorptivity of the polysilicon layer included in the measurement substrate according to the example.

### DETAILED DESCRIPTION

A stacked substrate of an embodiment is a stacked substrate for separating a semiconductor substrate using thermal expansion by a laser beam, the stacked substrate including the semiconductor substrate, a first insulating layer disposed above the semiconductor substrate, and a polysilicon layer that is disposed in contact with the first insulating layer, a thickness of the polysilicon layer being larger than a thickness of the first insulating layer in a direction perpendicular to a surface of the semiconductor substrate, and the polysilicon layer being doped with phosphorus.

Hereinafter, embodiments of the present invention will be described in detail with reference to the drawings. The present invention is not limited to the following embodiments. In addition, the components in the following embodiments include components that can be easily assumed by those skilled in the art or substantially same components.

### Configuration Example of Semiconductor Device

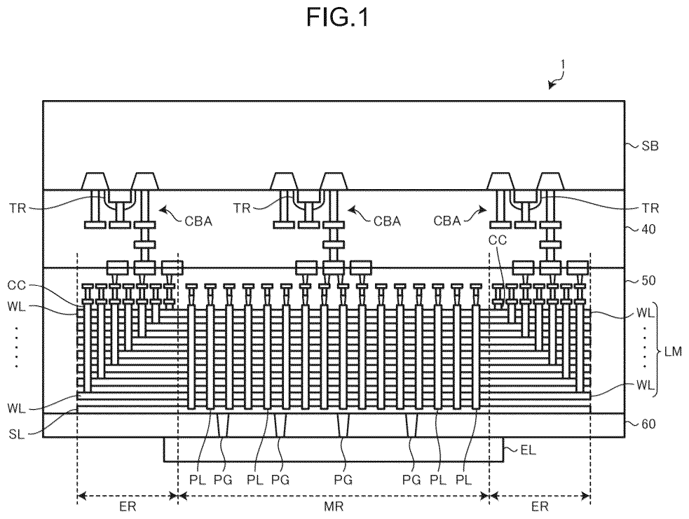

FIG. 1 is a cross-sectional view illustrating a configuration example of a semiconductor device 1 according to an embodiment. Here, in FIG. 1, hatching is omitted in consideration of visibility of the drawing.

As illustrated in FIG. 1, the semiconductor device 1 includes an electrode film EL, a source line SL, and a stacked body LM in which a plurality of word lines WL are stacked in order from the lower side of the drawing. In addition, the semiconductor device 1 includes a peripheral circuit CBA provided on a semiconductor substrate SB above the stacked body LM.

The source line SL is disposed on the electrode film EL via an insulating layer 60. The source line SL is, for example, a polysilicon layer or the like.

A plurality of plugs PG are arranged in the insulating layer 60, and the source line SL and the electrode film EL maintain electrical conduction via the plugs PG. As a result, a source potential can be applied to the source line SL from the outside of the semiconductor device 1 via the electrode film EL and the plugs PG.

The stacked body LM in which the plurality of word lines WL are stacked is disposed on the source line SL. A memory region MR is disposed in the central portion of the stacked body LM, and contact regions ER are arranged at both ends of the stacked body LM.

In the memory region MR, pillars PL as a plurality of memory pillars penetrating the word lines WL in a stacking direction are arranged. A plurality of memory cells are formed at intersections of the pillars PL and the word lines WL. As a result, the semiconductor device 1 is configured as, for example, a three-dimensional nonvolatile memory in which memory cells are three-dimensionally arranged in the memory region MR.

In the contact region ER, a plurality of contacts CC connected to the plurality of word lines WL are arranged. In the present specification, in the extending direction of the contact CC, the connection end side of the contact CC and the word line WL is defined as the lower side of the semiconductor device 1.

From the contact CC, a write voltage, a read voltage, and the like are applied to a memory cell included in the memory region MR in the central portion of the stacked body LM via the word line WL at the same height position as the memory cell. In this manner, the word lines WL stacked in multiple layers are individually drawn out by these contacts CC.

The plurality of word lines WL, pillars PL, and contacts CC are covered with an insulating layer 50. The insulating layer 50 also extends around the plurality of word lines WL.

The semiconductor substrate SB above the insulating layer 50 is, for example, a silicon substrate or the like. The peripheral circuit CBA including a transistor TR, wiring, and the like is disposed on the surface of the semiconductor substrate SB. Various voltages applied from the contact CC to the memory cell are controlled by the peripheral circuit CBA electrically connected to the contact CC. In this manner, the peripheral circuit CBA controls the electrical operation of the memory cell.

The peripheral circuit CBA is covered with an insulating layer 40, and the insulating layer 40 and the insulating layer 50 covering the stacked body LM are joined to each other, thereby forming the semiconductor device 1 including the configuration of the plurality of word lines WL, pillars PL, contacts CC, and the like, and the peripheral circuit CBA.

### Method of Manufacturing Semiconductor Device

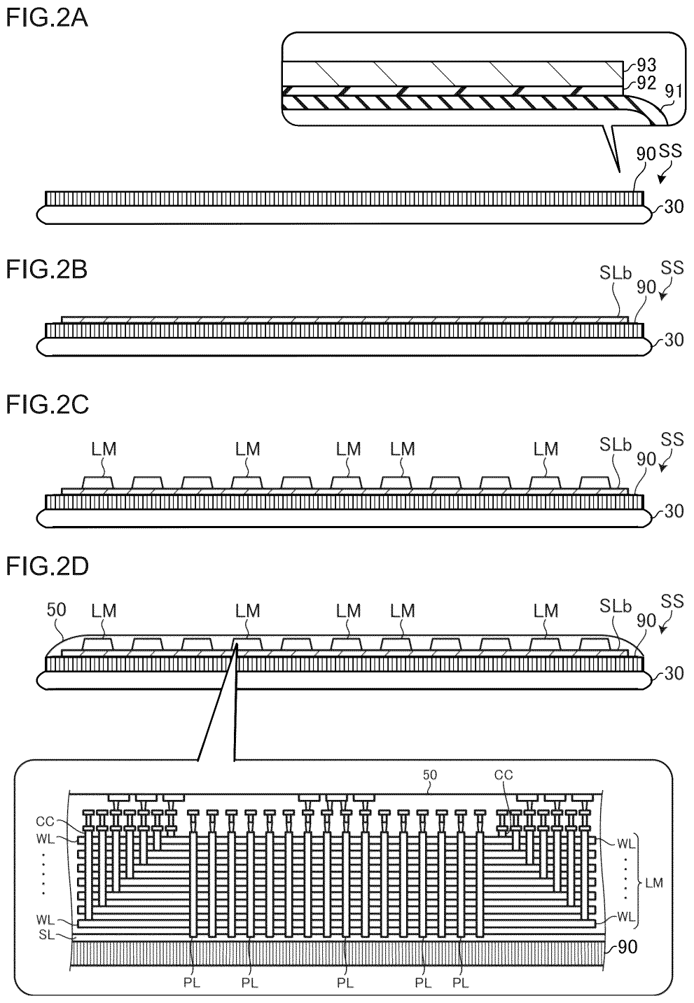

Next, a method of manufacturing the semiconductor device 1 of the embodiment will be described with reference to FIGS. 2A to 9C. The method of manufacturing the semiconductor device 1 may partially include a method of manufacturing a support substrate SS, a method of separating (peeling off, debonding, lifting off) the support substrate SS, and a method of regenerating the support substrate SS.

FIGS. 2A to 8E are diagrams sequentially illustrating a part of a procedure of the method of manufacturing the semiconductor device 1 according to the embodiment. FIGS. 2A to 8E are cross-sectional views of the semiconductor device 1 in the middle of manufacturing, unless otherwise specified.

As illustrated in FIG. 2A, a semiconductor substrate 30 such as a silicon substrate is prepared. After both surfaces of the semiconductor substrate 30 are cleaned, an insulating layer 91 such as a silicon nitride layer is formed.

The insulating layer 91 is formed on both surfaces of the semiconductor substrate 30 with a thickness of 50 nm or more and 100 nm or less, for example, 70 nm by using chemical vapor deposition (CVD) or the like. Here, as described later, in the embodiment, damage to the semiconductor substrate 30 in a step of separating the support substrate SS described later is prevented or reduced. Therefore, the insulating layer 91 used for surface protection does not need to be formed.

Furthermore, for example, an insulating layer 92 and a polysilicon layer 93 are formed in this order from the semiconductor substrate 30 side on the semiconductor substrate 30 covered with the insulating layer 91.

The insulating layer 92 is a silicon oxide layer or the like, and has a layer thickness of, for example, 20 nm or more and 50 nm or less. The insulating layer 92 functions as a heat insulating layer that insulates the semiconductor substrate 30 from heat of the polysilicon layer 93 serving as a heat generating source in the step of separating the support substrate SS described later.

The polysilicon layer 93 is formed thicker than the insulating layer 92, and has a layer thickness of, for example, 100 nm or more and 300 nm or less. In addition, the polysilicon layer 93 is doped with phosphorus. By doping the polysilicon layer 93 with phosphorus, the absorptivity of light having a wavelength of 9 μm or more and 10 μm or less can be increased, and the polysilicon layer 93 can be thermally expanded to cleave the insulating layer 92 and the polysilicon layer 93 in the step of separating the support substrate SS described later.

The phosphorus concentration of the polysilicon layer 93 is, for example, 1.5×10²⁰ atom/cm³ or more, more preferably 3.0×10²⁰ atom/cm³ or more. As a result, in a non-doped polysilicon layer, the absorptivity of light having a wavelength of 9 μm or more and 10 μm or less is 0%, whereas in the polysilicon layer 93 with the phosphorus concentration mentioned above, the absorptivity can be increased to, for example, 50% or more, more preferably 75% or more.

As a result, the polysilicon layer 93 can generate heat by the light having the wavelength mentioned above and thermally expand. The thermal conductivity of the polysilicon layer 93 is 10 times or more higher than the thermal conductivity of the insulating layer 92 such as a silicon oxide layer. In addition, when the thermal conductivities of the individual layers in the support substrate SS are compared, the thermal conductivity of the insulating layer 91 such as a silicon nitride layer and the thermal conductivity of the semiconductor substrate 30 such as a silicon substrate are 10 times or more higher than the thermal conductivity of the insulating layer 92 such as a silicon oxide layer.

As described above, the support substrate SS in which a multilayer structure 90 including the insulating layers 91 and 92 and the polysilicon layer 93 is formed on the semiconductor substrate 30 is manufactured. As described above, the support substrate SS is configured as a stacked substrate in which a plurality of layers are formed on the semiconductor substrate 30.

As illustrated in FIG. 2B, a conductive layer SLb is formed on the multilayer structure 90 of the support substrate SS. The conductive layer SLb is, for example, a polysilicon layer or the like, and later becomes the source line SL of the semiconductor device 1. Here, when the conductive layer SLb is formed on the multilayer structure 90, the conductive layer SLb may be formed via another layer such as a silicon oxide layer or a polysilicon layer. The layer interposed between the multilayer structure 90 and the conductive layer SLb may have a single-layer structure, a multilayer structure of the same type of layers, a multilayer structure of different types of layers, or the like.

Furthermore, the conductive layer SLb does not need to be formed on the support substrate SS at this stage. In that case, for example, the conductive layer SLb can be formed after being bonded to the semiconductor substrate SB described later and processed into the source line SL.

As illustrated in FIG. 2C, a plurality of stacked bodies LM in which a plurality of word lines WL are stacked apart from each other are formed on the conductive layer SLb. As illustrated in the enlarged cross-sectional view in FIG. 2D, the plurality of pillars PL, the plurality of contacts CC, and the like are formed in each of the stacked bodies LM.

Such a stacked body LM in which the pillars PL, the contacts CC, and the like are formed is formed as follows. That is, a stacked body in which a plurality of silicon nitride layers and a plurality of silicon oxide layers are alternately stacked one by one is formed on the conductive layer SLb formed on the support substrate SS.

In addition, a plurality of contact holes reaching the individual silicon nitride layers are formed in a partial region of the stacked body. A memory hole penetrating the stacked body and reaching the conductive layer SLb is further formed, and the memory hole is filled with a memory layer, a semiconductor layer, and the like. At this time, the memory layer on the side surface of the semiconductor layer is partially removed to electrically connect the semiconductor layer and the conductive layer SLb.

Thereafter, the word lines WL are formed by replacing the plurality of silicon nitride layers of the stacked body with conductive layers by a process called a replacement process. In addition, the plurality of contact holes are filled with a conductive layer or the like to form the contacts CC, and upper layer wiring or the like is formed on the stacked body LM.

As illustrated in FIG. 2D, the insulating layer 50 covering the plurality of stacked bodies LM in which the plurality of pillars PL, the plurality of contacts CC, and the like are formed as described above is formed. Electrode pads electrically connected to the pillars PL, the contacts CC, and the like of the stacked body LM are formed on the surface of the insulating layer 50.

The insulating layer 50 including the plurality of stacked bodies LM in which the plurality of pillars PL and the like are formed is an example of a device layer including at least a part of the configuration of the semiconductor device 1.

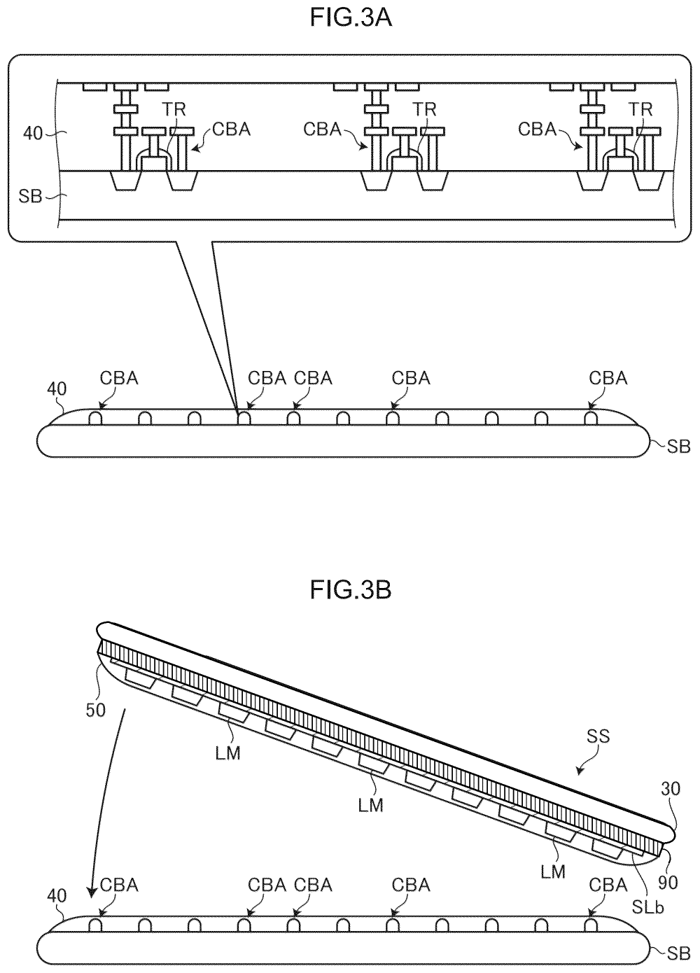

As illustrated in FIG. 3A, the plurality of peripheral circuits CBA including the transistors TR are formed on the semiconductor substrate SB separate from the support substrate SS. The plurality of peripheral circuits CBA are formed so as to individually correspond to, for example, the plurality of stacked bodies LM. In addition, the insulating layer 40 covering the peripheral circuits CBA is formed. An electrode pad electrically connected to the transistor TR or the like of the peripheral circuit CBA is formed on the surface of the insulating layer 40.

As illustrated in FIG. 3B, the surface of the support substrate SS on which the stacked body LM and the like are formed faces the surface of the semiconductor substrate SB on which the peripheral circuit CBA and the like are formed, the insulating layer 50 on the support substrate SS side and the insulating layer 40 on the semiconductor substrate SB side are joined, and the support substrate SS and the semiconductor substrate SB are bonded.

These insulating layers 50 and 40 can be joined by, for example, activating the surfaces in advance by a plasma treatment or the like. When the insulating layers 50 and 40 are joined, the support substrate SS and the semiconductor substrate SB are aligned in a manner that the electrode pad formed on the insulating layer 50 and the electrode pad formed on the insulating layer 40 overlap each other.

After the insulating layers 50 and 40 are joined, an annealing treatment is performed to join both electrode pads by, for example, Cu—Cu joining. As a result, the stacked body LM and the peripheral circuit CBA corresponding to each other are electrically connected, and the support substrate SS and the semiconductor substrate SB are bonded.

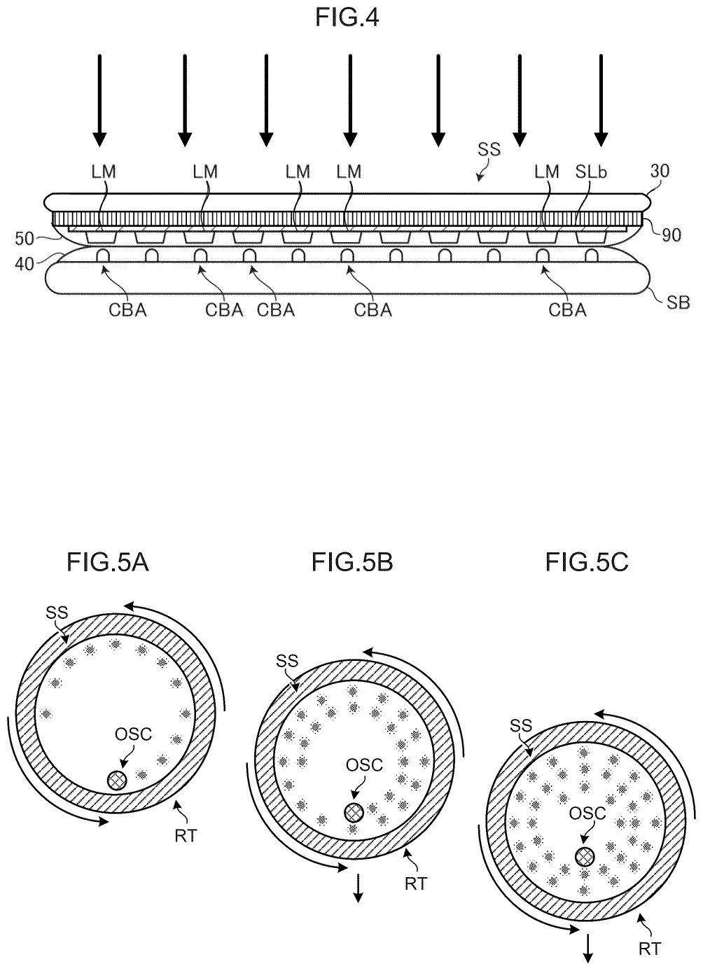

As illustrated in FIG. 4, the bonded body of the support substrate SS and the semiconductor substrate SB is irradiated with a laser beam having a wavelength of, for example, 9 μm or more and 10 μm or less from the support substrate SS side. As the laser beam, for example, a carbon dioxide (CO₂) laser having a wavelength of 9.6 μm can be used. Here, the wavelength of the laser beam may be, for example, 9.25 μm, 10.6 μm, or the like. In addition, the laser beam is preferably emitted in a pulsed manner. As a result, the entire surface of the support substrate SS can be irradiated with the laser beam.

As illustrated in the top views of FIGS. 5A to 5C, in a case where the entire surface of the support substrate SS is irradiated with a laser beam by the pulse laser, for example, the bonded body of the support substrate SS and the semiconductor substrate SB is placed on a stage RT that can be rotationally driven and horizontally driven, and the laser beam can be sequentially emitted in a pulsed manner from an laser oscillator OSC while the stage RT is rotated.

That is, every time the stage RT is rotated once to irradiate the support substrate SS with the laser beam circumferentially, the stage RT is moved in the horizontal direction to shift the irradiation position, and then the stage RT is further rotated, so that the entire surface of the support substrate SS can be irradiated with the laser beam concentrically.

At this time, as in the examples of FIGS. 5A to 5C, the laser beam may be emitted concentrically from the outer peripheral side toward the central portion of the support substrate SS, or the laser beam may be emitted concentrically from the central portion toward the outer peripheral side of the support substrate SS, unlike the examples of FIGS. 5A to 5C.

The pitch of the irradiation position of the laser beam can be, for example, an interval of a dozen μm, and the pulse frequency can be, for example, 10 kHz or more and 100 kHz or less.

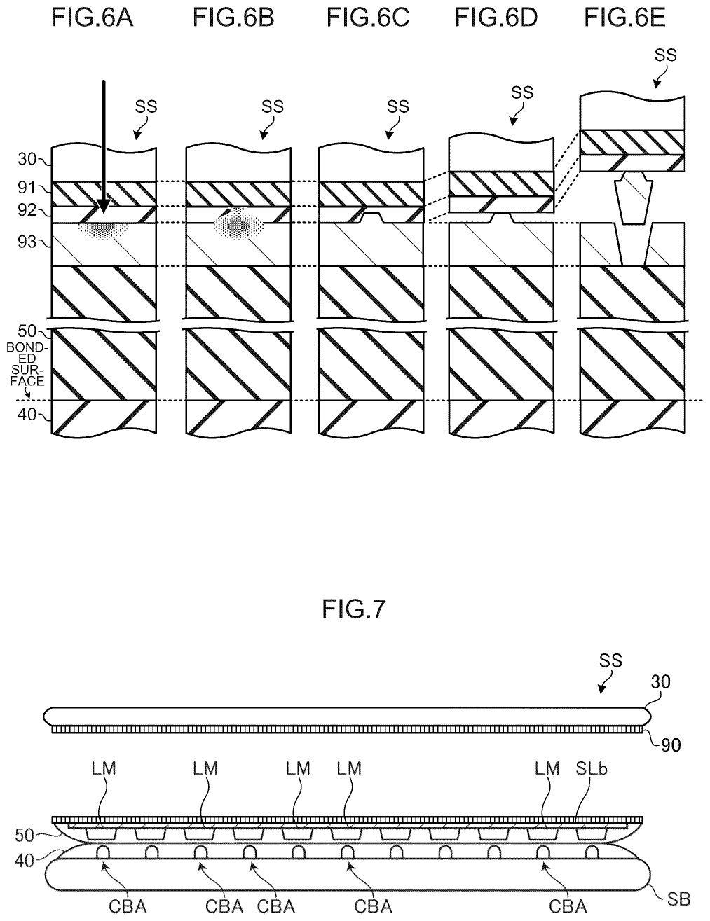

As described above, by irradiating the support substrate SS with the laser beam, the polysilicon layer 93 of the multilayer structure 90 formed on the semiconductor substrate 30 is thermally expanded, and the polysilicon layer 93 and the insulating layer 92 are cleaved. This state is illustrated in FIGS. 6A to 6E.

As illustrated in FIG. 6A, by irradiation with the laser beam, the phosphorus-doped polysilicon layer 93 with a higher laser beam absorptivity than the insulating layer 92 or the like absorbs the laser beam and generates heat.

As illustrated in FIG. 6B, the insulating layer 92 also slightly generates heat by irradiation with the laser beam, but the amount of heat generated by the insulating layer 92 is lower than that of the polysilicon layer 93. In addition, as described above, the thermal conductivity of the insulating layer 92 is 1/10 or less the thermal conductivity of the polysilicon layer 93. For this reason, the insulating layer 92 can function as a heat insulating layer that prevents or reduces heat from the polysilicon layer 93 from being transferred to the semiconductor substrate 30.

In a case where the insulating layer 92 functions as a heat insulating layer, the insulating layer 92 preferably has a layer thickness of, for example, 20 nm or more and 50 nm or less as described above. In a case where the insulating layer 92 is too thick, the insulating layer 92 itself serves as a heat generating source, the heat insulating effect of the insulating layer 92 is weakened, and heat may be transferred to the semiconductor substrate 30. When heat is transferred to the semiconductor substrate 30, the semiconductor substrate 30 itself is thermally expanded, and damage such as lattice defects may occur in the crystal of the semiconductor substrate 30.

On the other hand, in a case where the insulating layer 92 is not provided on the support substrate SS, heat of the polysilicon layer 93 is transferred to the semiconductor substrate 30 and dissipated, so that stress to be described later generated by thermal expansion of the polysilicon layer 93 is dispersed, and it is difficult to separate (peel off, debond, lift off) the support substrate SS.

As illustrated in FIG. 6C, the polysilicon layer 93 thermally expands. As a result, stress is generated between the polysilicon layer 93 and the insulating layer 92.

As illustrated in FIG. 6D, the insulating layer 92 is pushed up by the stress of the thermally expanded polysilicon layer 93, and the interface between the polysilicon layer 93 and the insulating layer 92 is cleaved.

As illustrated in FIG. 6E, due to the cleavage occurring at the interface between the polysilicon layer 93 and the insulating layer 92, the support substrate SS is separated in a manner that the insulating layers 92 and 91 are attached to the semiconductor substrate 30 side. At this time, the thermally expanded portion of the polysilicon layer 93 is separated together with the insulating layers 92 and 91 and the like while being attached to the insulating layer 92.

As described above, the support substrate SS can be separated at a relatively low temperature by cleaving the polysilicon layer 93 and the insulating layer 92 using thermal expansion of the polysilicon layer 93. Therefore, the support substrate SS is removed without spraying or melting a member serving as a starting point of cleavage of the polysilicon layer 93 and the insulating layer 92 or causing a chemical change.

As illustrated in FIG. 7, the support substrate SS that has become the semiconductor substrate 30 including only a part of the multilayer structure 90 such as the insulating layers 92 and 91 is separated, so that the peripheral circuit CBA including the transistor TR and the like formed on the semiconductor substrate SB, and the stacked body LM bonded above the peripheral circuit CBA via the insulating layers 40 and 50 and including the pillars PL and the like remain on the semiconductor substrate SB side.

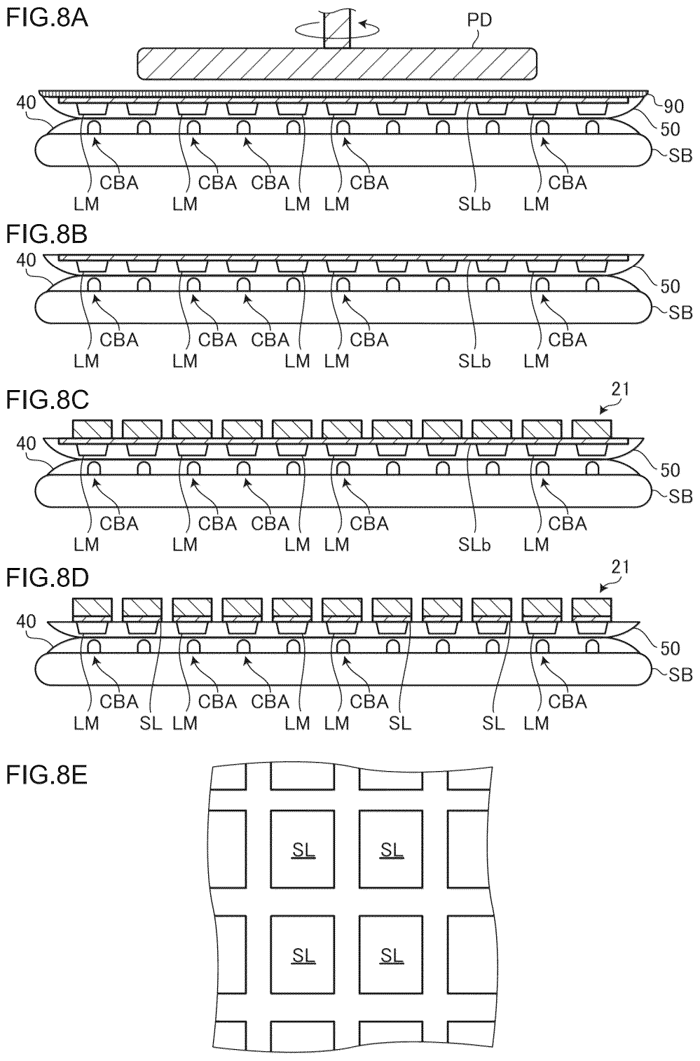

As illustrated in FIG. 8A, the multilayer structure 90 remaining on the conductive layer SLb side of the stacked body LM joined on the semiconductor substrate SB is ground and removed using a polishing pad PD by chemical mechanical polishing (CMP) or the like.

As illustrated in FIG. 8B, by grinding and removing the multilayer structure 90, the conductive layer SLb is exposed on the upper surface of the semiconductor substrate SB.

As illustrated in FIG. 8C, a resist pattern 21 having a pattern corresponding to the arrangement of the individual stacked bodies LM is formed on the conductive layer SLb.

As illustrated in FIG. 8D, the conductive layer SLb is etched via the resist pattern 21 to form a pattern of the plurality of source lines SL separated for the individual stacked bodies LM.

As illustrated in the top view of FIG. 8E, for example, in accordance with the arrangement of the plurality of stacked bodies LM arranged in a grid shape in the plane of the semiconductor substrate SB, the source lines SL are also formed in a grid pattern, for example.

After the source lines SL are formed in a plurality of patterns, the resist pattern 21 is removed by an ashing treatment using oxygen plasma or the like.

Thereafter, the electrode film EL connected to the source line SL via the plug PG formed in the insulating layer 60 is formed, and the semiconductor substrate SB is divided so as to include at least one stacked body LM, so that the semiconductor device 1 of the embodiment is manufactured.

On the other hand, the support substrate SS separated from the semiconductor substrate SB is subjected to a regeneration process described below and reused as the support substrate SS used for manufacturing a new semiconductor device 1.

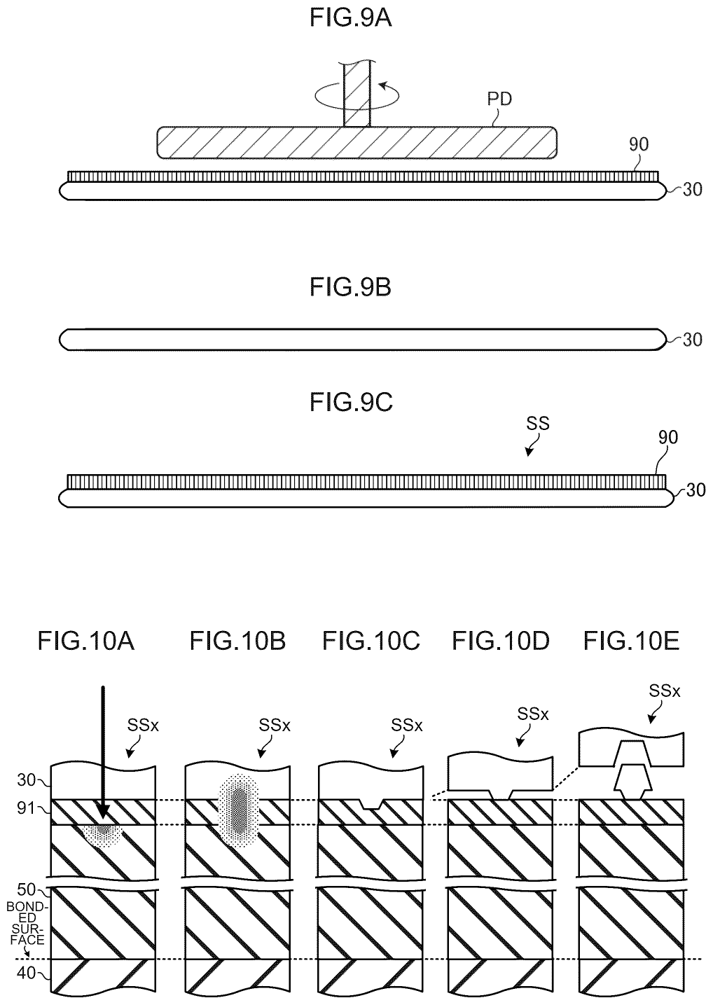

FIGS. 9A to 9C are cross-sectional views illustrating a part of a procedure of the regeneration process of the support substrate SS according to the embodiment.

As illustrated in FIG. 9A, the multilayer structure 90 remaining on the support substrate SS side due to cleavage is ground and removed using the polishing pad PD. The multilayer structure 90 may be removed by wet etching or the like.

As illustrated in FIG. 9B, by grinding and removing the multilayer structure 90, the semiconductor substrate 30 in a substantially initial state can be obtained.

Thereafter, the process illustrated in FIG. 2A is performed on the semiconductor substrate 30.

That is, after cleaning the semiconductor substrate 30 as illustrated in FIG. 9C, both surfaces of the semiconductor substrate 30 are covered with, for example, the insulating layer 91. In addition, the insulating layer 92 and the phosphorus-doped polysilicon layer 93 are formed in this order from the semiconductor substrate 30 side on the semiconductor substrate 30.

As described above, the support substrate SS is regenerated from the used semiconductor substrate 30. The regeneration process of the support substrate SS illustrated in FIGS. 9A to 9C may also be included in the method of manufacturing the support substrate SS.

### Overview

In some cases, a semiconductor device such as a three-dimensional nonvolatile memory is manufactured by, for example, forming a stacked body including a plurality of pillars on a support substrate and bonding the support substrate including the stacked body to a semiconductor substrate on which a peripheral circuit is separately formed. The support substrate is bonded to the semiconductor substrate and then separated to be repeatedly reused.

The support substrate is separated by thermally expanding the semiconductor substrate constituting the support substrate by, for example, irradiation with a laser beam or the like and generating a cleavage with other members on the surface of the semiconductor substrate. This state is illustrated in FIGS. 10A to 10E. FIGS. 10A to 10E are schematic cross-sectional views illustrating a state of separating of a support substrate SSx according to a comparative example.

As illustrated in FIG. 10A, the support substrate SSx includes the semiconductor substrate 30 and the insulating layer 91 such as a silicon nitride layer that protects the semiconductor substrate 30. The insulating layer 50 as a device layer is formed on the insulating layer 91 of the support substrate SSx, and the insulating layer 50 is joined to the insulating layer 40 covering the peripheral circuit and the like.

The bonded body described above is irradiated with a laser beam having a wavelength of, for example, 9 μm or more and 10 μm or less from the support substrate SSx side. As a result, the insulating layer 50 generates heat. Here, the thermal conductivity of the insulating layer 91 such as a silicon nitride layer and the thermal conductivity of the semiconductor substrate 30 such as a silicon substrate are 10 times or more higher than the thermal conductivity of the insulating layer 50 such as a silicon oxide layer.

As illustrated in FIG. 10B, heat of the insulating layer 50 is transferred to the semiconductor substrate 30 with a higher thermal conductivity than the insulating layer 50 through the insulating layer 91 with a higher thermal conductivity than the insulating layer 50.

As illustrated in FIG. 10C, the insulating layer 91 side of the semiconductor substrate 30 thermally expands.

As illustrated in FIG. 10D, the thermally expanded portion of the semiconductor substrate 30 pushes down the insulating layer 91, and the interface between the semiconductor substrate 30 and the insulating layer 91 is cleaved.

As illustrated in FIG. 10E, the support substrate SSx including only the semiconductor substrate 30 is separated by the cleavage occurring at the interface between the semiconductor substrate 30 and the insulating layer 91. At this time, the thermally expanded portion of the semiconductor substrate 30 remains on the insulating layers 40 and 50 side while being attached to the insulating layer 91.

As described above, when the support substrate SSx is separated using thermal expansion of the semiconductor substrate 30 itself, damage such as lattice defects occurs in the thermally expanded semiconductor substrate 30. In addition, since the thermally expanded portion of the semiconductor substrate 30 remains on the insulating layers 40 and 50 side, further damage such as unevenness occurs on the surface of the semiconductor substrate 30.

When damage such as lattice defects and unevenness occurs in the semiconductor substrate 30, it is necessary to remove not only the insulating layer 91 on the semiconductor substrate 30 but also a damaged portion of the semiconductor substrate 30 at the time of regenerating the support substrate SSx. As a result, the semiconductor substrate 30 becomes thin every time the regeneration is repeated, and the number of times that the support substrate SSx can be regenerated decreases.

The support substrate SS according to the embodiment includes the insulating layer 92 disposed above the semiconductor substrate 30 and the polysilicon layer 93 that is disposed above the insulating layer 92 and doped with phosphorus.

As described above, the phosphorus-doped polysilicon layer 93 has a property of absorbing a laser beam, and serves as a starting point causing cleavage in the multilayer structure 90. The insulating layer 92 is less likely to absorb a laser beam than the polysilicon layer 93, and prevents or reduces heat generated in the polysilicon layer 93 from being transferred to the semiconductor substrate 30. As a result, damage to the semiconductor substrate 30 can be prevented or reduced when the support substrate SS is separated.

According to the support substrate SS of the embodiment, the polysilicon layer 93 has a phosphorus concentration of 1.5×10²⁰ atom/cm³ or more, more preferably 3.0×10²⁰ atom/cm³ or more. As a result, in the polysilicon layer 93, the absorptivity of light having a wavelength of 9 μm or more and 10 μm or less can be increased.

According to the support substrate SS of the embodiment, in the polysilicon layer 93, the absorptivity of light having a wavelength of 9 μm or more and 10 μm or less is 50% or more, and more preferably 75% or more. As a result, the laser beam having the wavelength described above is absorbed by the polysilicon layer 93, and the polysilicon layer 93 can be thermally expanded.

According to the support substrate SS of the embodiment, the polysilicon layer 93 has a thermal conductivity 10 times or more higher than the insulating layer 92. As a result, the polysilicon layer 93 can be thermally expanded efficiently.

According to the support substrate SS of the embodiment, the thickness of the insulating layer 92 between the semiconductor substrate 30 and the polysilicon layer 93 is 20 nm or more and 50 nm or less. As a result, the insulating layer 92 can function as a heat insulating layer. Therefore, heat transfer from the polysilicon layer 93 to the semiconductor substrate 30 is prevented or reduced, and damage to the semiconductor substrate 30 is prevented or reduced.

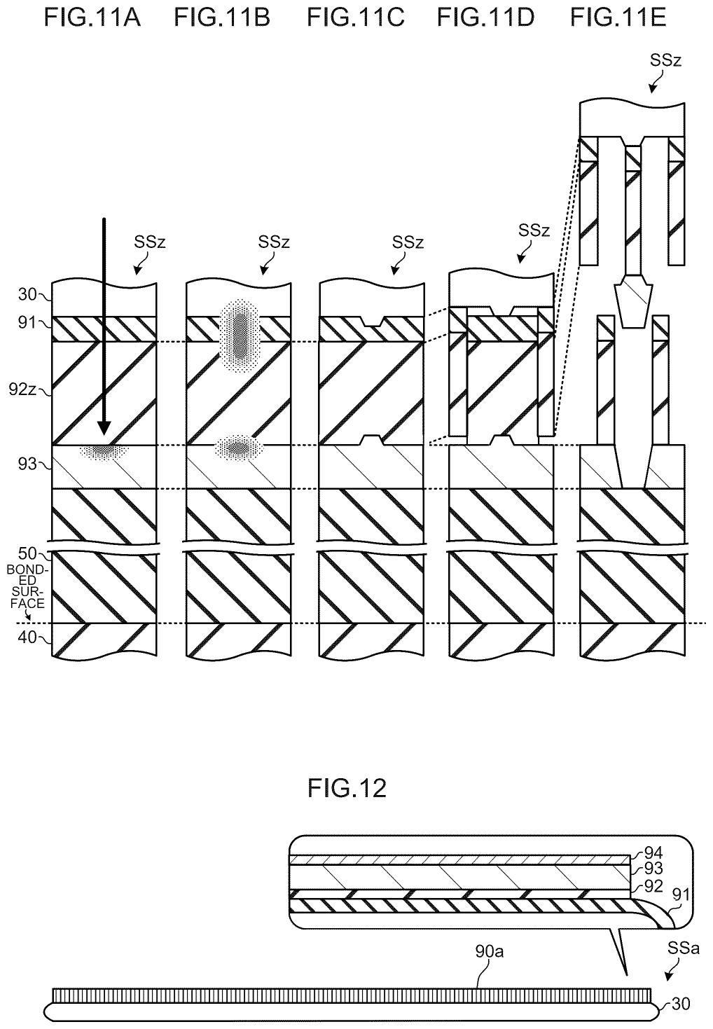

Here, FIGS. 11A to 11E illustrate a state in a case where a support substrate SSz of the comparative example having an insulating layer 92z thicker than the insulating layer 92 of the embodiment is used. FIGS. 11A to 11E are schematic cross-sectional views illustrating a state of separating of the support substrate SSz according to the comparative example.

As illustrated in FIG. 11A, the support substrate SSz includes the semiconductor substrate 30, the insulating layer 91, the insulating layer 92z such as a silicon oxide layer, and the phosphorus-doped polysilicon layer 93. The insulating layer 92z included in the support substrate SSz has a layer thickness of, for example, 200 nm.

The insulating layer 50 as a device layer is formed on the polysilicon layer 93 of the support substrate SSz, and the insulating layer 50 is joined to the insulating layer 40 covering the peripheral circuit and the like.

The bonded body described above is irradiated with a laser beam having a wavelength of, for example, 9 μm or more and 10 μm or less from the support substrate SSz side. As a result, the polysilicon layer 93 generates heat.

As illustrated in FIG. 11B, at this time, the insulating layer 92z having a thickness of, for example, 200 nm also generates heat. Heat of the insulating layer 92z is also transferred to the semiconductor substrate 30 via the insulating layer 91.

As illustrated in FIG. 11C, the insulating layer 92z side of the polysilicon layer 93 thermally expands, and the insulating layer 91 side of the semiconductor substrate 30 also thermally expands.

As illustrated in FIG. 11D, when the semiconductor substrate 30 thermally expands, the thermally expanded portion of the semiconductor substrate 30 pushes down the insulating layer 91, and cleavage occurs at two points, or the interface between the semiconductor substrate 30 and the insulating layer 91 and the interface between the insulating layer 92z and the polysilicon layer 93.

As illustrated in FIG. 11E, the support substrate SSz is separated in a manner that the thermally expanded portion of the polysilicon layer 93 is attached to the insulating layer 92z, and furthermore, the insulating layer 92z with the thermally expanded portion of the polysilicon layer 93 and the insulating layer 91 are attached to the thermally expanded portion of the semiconductor substrate 30.

In the separating method described above, heat is also transferred to the semiconductor substrate 30, and thus lattice defects and the like occur in the crystal of the semiconductor substrate 30.

In the support substrate SS of the embodiment, as described above, by appropriately adjusting the thickness of the insulating layer 92, it is possible to prevent or reduce heat transfer to the semiconductor substrate 30 and to prevent or reduce damage to the semiconductor substrate 30 by the heat insulating effect of the insulating layer 92 while preventing or reducing the insulating layer 92 itself from becoming a heat generating source.

According to the support substrate SS of the embodiment, the thickness of the polysilicon layer 93 is 100 nm or more and 300 nm or less. As described above, by forming the polysilicon layer 93 thicker than the insulating layer 92, stress can be generated by thermal expansion of the polysilicon layer 93, and the interface with the insulating layer 92 can be cleaved.

### First Modification

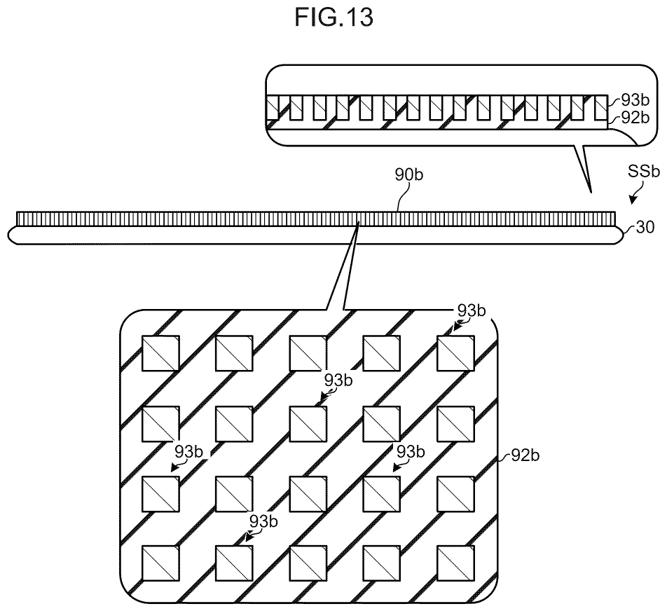

Next, a support substrate SSa of a first modification of the embodiment will be described with reference to FIG. 12. The support substrate SSa of the first modification is different from that of the embodiment described above in that the support substrate SSa includes a metal layer 94 in addition to the layers described above.

FIG. 12 is a cross-sectional view illustrating an example of a configuration of the support substrate SSa according to the first modification of the embodiment. In the following drawings, the same reference numerals are given to the same configurations as those of the embodiment described above, and the description thereof may be omitted.

As illustrated in FIG. 12, the support substrate SSa of the first modification has a configuration in which a multilayer structure 90a is formed on a semiconductor substrate 30. The multilayer structure 90a includes the insulating layer 91 covering both surfaces of the semiconductor substrate 30, and further includes the insulating layer 92, the polysilicon layer 93, and the metal layer 94 in this order from the semiconductor substrate 30 side.

The metal layer 94 may be, for example, a transition metal layer such as a titanium layer, a tantalum layer, a tungsten layer, a molybdenum layer, a copper layer, a platinum layer, or a gold layer, or may be an oxide layer of these transition metals.

As a result, when the support substrate SSa is separated, the laser beam transmitted through the polysilicon layer 93 can be reflected again to the polysilicon layer 93 by the metal layer 94 in which the reflectance of a light beam having a wavelength of 9 μm or more and 10 μm or less is higher than that of the polysilicon layer 93. Therefore, the absorption efficiency of the laser beam in the polysilicon layer 93 can be further enhanced, and the thermal expansion of the polysilicon layer 93 can be further promoted.

The layer that is provided on the polysilicon layer 93 and functions as a reflection layer does not need to contain metal as long as it is a layer having a higher reflectance than the polysilicon layer 93, and may be, for example, a polysilicon layer or the like having a phosphorus concentration higher than the polysilicon layer 93.

According to the support substrate SSa of the first modification, other effects similar to those of the support substrate SS of the embodiment described above are also obtained.

### Second Modification

Next, a support substrate SSb of a second modification of the embodiment will be described with reference to FIGS. 13 to 15B. The support substrate SSb of the second modification is different from that of the embodiment described above in that the support substrate SSb includes a polysilicon layer 93b divided into a plurality of patterns.

In the following drawings, the same reference numerals are given to the same configurations as those of the embodiment described above, and the description thereof may be omitted.

FIG. 13 is a cross-sectional view illustrating an example of a configuration of the support substrate SSb according to the second modification of the embodiment. As illustrated in FIG. 13, the support substrate SSb of the second modification has a configuration in which a multilayer structure 90b is formed on the semiconductor substrate 30. The multilayer structure 90b includes an insulating layer 92b and the polysilicon layer 93b.

Here, the support substrate SSb may have the insulating layer 91 such as a silicon nitride layer covering both surfaces of the semiconductor substrate 30, similarly to the embodiment described above. That is, the multilayer structure 90b of the second modification may further include the insulating layer 91.

The insulating layer 92b is a silicon oxide layer or the like disposed on the semiconductor substrate 30, and a part of the insulating layer 92b reaches the height position of the upper surface of the polysilicon layer 93b. The layer thickness of the insulating layer 92b between the lower end of the polysilicon layer 93b and the upper surface of the semiconductor substrate 30 is, for example, 20 nm or more and 50 nm or less.

The polysilicon layer 93b is doped with phosphorus of, for example, 1.5×10²⁰ atom/cm³ or more, more preferably 3.0×10²⁰ atom/cm³ or more, and has a layer thickness of, for example, 100 nm or more and 300 nm or less.

In addition, the polysilicon layer 93b is divided into a plurality of patterns when viewed from the stacking direction of the insulating layer 92b and the polysilicon layer 93b, and a part of the polysilicon layer 93b is buried in the insulating layer 92b reaching the height position of the upper surface of the polysilicon layer 93b. More specifically, the upper end of the polysilicon layer 93b is exposed on the upper surface of the insulating layer 92b, and the lower end is located at a predetermined depth in the insulating layer 92b.

The shape of each of the polysilicon layers 93b divided into the plurality of patterns is, for example, a rectangular shape when viewed from the stacking direction of the insulating layer 92b and the polysilicon layer 93b. Here, the shape of the polysilicon layer 93b is not limited to a rectangular shape, and may be, for example, a polygon, a circle, an ellipse, or the like.

The size of the upper surface of each polysilicon layer 93b is, for example, 100 nm or more and 1000 nm or less. Here, the size of the upper surface of the polysilicon layer 93b can be determined as the maximum width in a case where the polysilicon layer 93b has a polygonal shape such as a rectangle, and as the maximum diameter in a case where the polysilicon layer 93b has a circular shape or the like.

The polysilicon layers 93b divided into the plurality of patterns are dispersedly arranged in the insulating layer 92b in a grid shape, for example, when viewed from the stacking direction of the insulating layer 92b and the polysilicon layer 93b. Here, the arrangement of the polysilicon layers 93b is not limited to a grid shape, and the polysilicon layers 93b may be arranged in a zigzag shape or arranged radially or concentrically on the circular semiconductor substrate 30, for example.

When the pitch of the polysilicon layer 93b is defined as a distance connecting the center points of the upper surface shapes of the polysilicon layer 93b, the polysilicon layer 93b has a pitch of, for example, 100 nm or more and 1000 nm or less.

The support substrate SSb described above can be manufactured as follows.

That is, the insulating layer 92b having the layer thickness of the polysilicon layer 93b in addition to the layer thickness between the polysilicon layer 93b and the semiconductor substrate 30 is formed on the semiconductor substrate 30, and a plurality of recesses having the pattern of the polysilicon layer 93b are formed in the insulating layer 92b by reactive ion etching (RIE) or the like. Thereafter, the support substrate SSb described above is manufactured by filling the phosphorus-doped polysilicon layer 93b in the recesses.

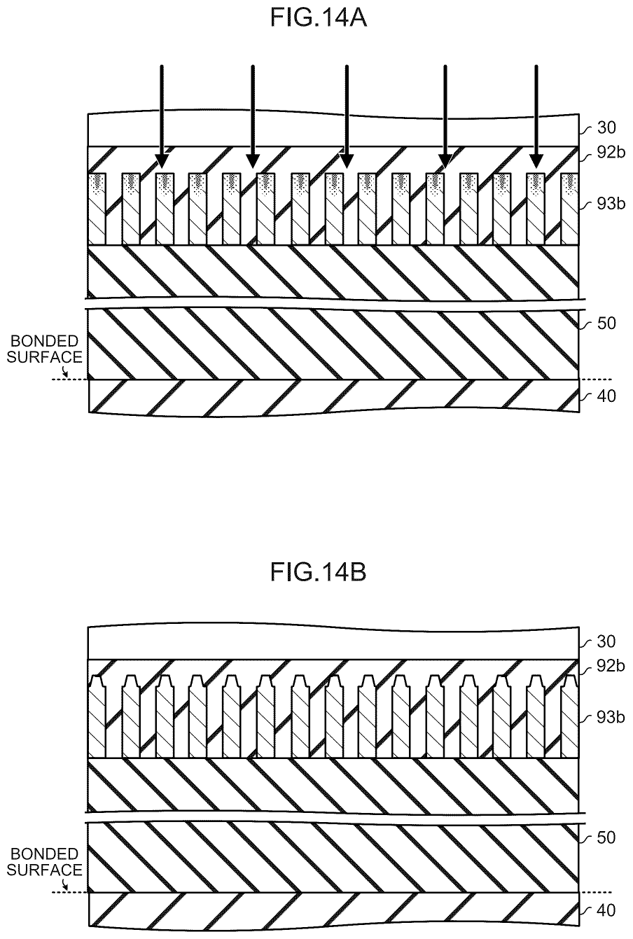

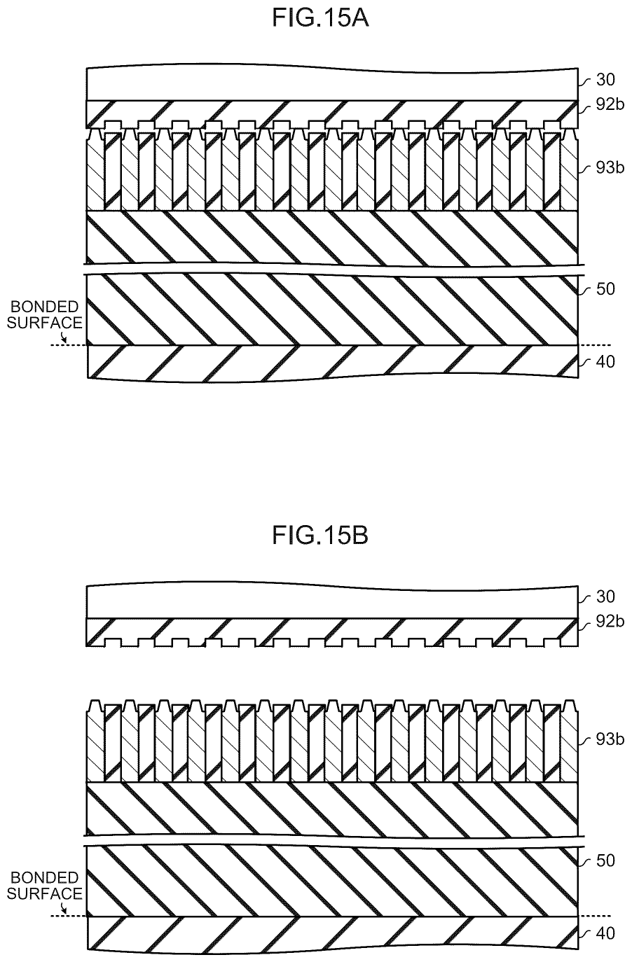

Next, a state where the support substrate SSb configured as described above is separated is illustrated in FIGS. 14A to 15B. FIGS. 14A to 15B are schematic cross-sectional views illustrating a state of separating of the support substrate SSb according to the second modification of the embodiment.

As illustrated in FIG. 14A, the support substrate SSb of the second modification and the semiconductor substrate SB on which the peripheral circuit CBA is formed are also bonded to each other by joining the insulating layer 50 formed on the support substrate SSb so as to include the pillar PL, the stacked body LM, and the like and the insulating layer 40 covering the peripheral circuit CBA of the semiconductor substrate SB.

The bonded body of the support substrate SSb and the semiconductor substrate SB is irradiated with a laser beam having a wavelength of, for example, 9 μm or more and 10 μm or less from the support substrate SSb side. At this time, for example, it is preferable to use a carbon dioxide gas laser having a wavelength of 10.6 μm having a spot diameter larger than that in the case of the embodiment described above. In addition, a laser beam may be continuously emitted, or may be emitted in a pulsed manner. In a case where the laser beam is emitted in a pulsed manner, the pitch of the irradiation position of the laser beam can be set to, for example, 15 μm or less, more preferably 5 μm or less.

As a result, the polysilicon layer 93b divided into a plurality of patterns generates heat. At this time, the insulating layer 92b interposed between the upper end of the polysilicon layer 93b and the semiconductor substrate 30 prevents or reduces heat from the polysilicon layer 93b from being transferred to the semiconductor substrate 30. In addition, the insulating layer 92b interposed between the polysilicon layers 93b divided into the plurality of patterns prevents or reduces heat transfer between the polysilicon layers 93b.

As illustrated in FIG. 14B, each of the polysilicon layers 93b divided into the plurality of patterns thermally expands.

As illustrated in FIG. 15A, the insulating layer 92b interposed between the upper end of the polysilicon layer 93b and the semiconductor substrate 30 is pushed up by the thermally expanded portion of the polysilicon layer 93b, and the insulating layer 92b is cleaved at a height position near the upper end of the polysilicon layer 93b.

As illustrated in FIG. 15B, due to the cleavage generated in the insulating layer 92b at the height position near the upper end of the polysilicon layer 93b, the support substrate SSb is separated in a manner that the insulating layer 91b above the polysilicon layer 93b is attached to the semiconductor substrate 30 side.

Meanwhile, as described above, by making the pitch of the irradiation position of the laser beam finer and then emitting the laser beam in a pulsed manner or continuously emitting the laser beam, the number of cleavage sites due to thermal expansion of the polysilicon layer increases. Therefore, stress applied to the semiconductor substrate at the time of separating the support substrate can be further reduced, and damage to the semiconductor substrate can be further reduced.

However, for example, in a case where the polysilicon layer is formed as a continuous layer, when the number of portions irradiated with the laser beam is increased, the entire polysilicon layer is thermally expanded. The stress that causes cleavage at the interface with the insulating layer is generated by a mixture of a thermally expandable portion and a non-thermally expandable portion in the polysilicon layer. Therefore, when the entire polysilicon layer is thermally expanded, it is difficult to separate the support substrate.

According to the support substrate SSb of the second modification, the polysilicon layer 93b is divided into a plurality of patterns when viewed from the stacking direction of the insulating layer 92b and the polysilicon layer 93b.

According to the above configuration, in the case of using the pulse laser in which the pitch of the irradiation position of the laser beam is made finer or the continuous irradiation with the laser beam, the polysilicon layer 93b thermally expands in each portion divided into the plurality of patterns. In addition, the insulating layer 92b filling the plurality of patterns of the polysilicon layer 93b functions as a heat insulating layer, and heat transfer between the polysilicon layers 93b can be prevented or reduced.

Therefore, stress can be generated in the insulating layer 92b interposed between the polysilicon layer 93b and the semiconductor substrate 30 and the insulating layer 92b can be cleaved, so that the support substrate SSb can be separated.

In addition, the number of cleavage sites of the insulating layer 92b is increased by the pulse laser with a finer pitch or the continuous irradiation with the laser beam, and the stress applied to the semiconductor substrate 30 is reduced, and thus damage to the semiconductor substrate 30 can be further prevented or reduced.

Furthermore, since a pulse laser having a large spot diameter or continuous irradiation with a laser beam can be used, the time required for separating the semiconductor substrate 30 can be shortened.

According to the support substrate SSb of the second modification, other effects similar to those of the support substrate SS of the embodiment described above are also obtained.

### Third Modification

In the second modification described above, by dividing the polysilicon layer 93b into a plurality of patterns, the thermally expanded portions of the polysilicon layer 93b are dispersed in the plane of the semiconductor substrate 30, and thus stress applied to the semiconductor substrate 30 is reduced.

On the other hand, it is also possible to promote separating of the semiconductor substrate 30 by limiting the direction of thermal expansion to any one in the vertical direction in the polysilicon layer serving as a heat generating source. In order to limit the direction of thermal expansion to any one in the vertical direction, it is conceivable that a layer having high hardness such as a silicon nitride layer is interposed on one side in the vertical direction of the polysilicon layer to prevent or reduce expansion of the polysilicon layer toward the layer having high hardness.

Furthermore, by disposing a high hardness layer such as a silicon nitride layer divided into a plurality of patterns on the other side in the vertical direction of the polysilicon layer, the thermally expanded portions of the polysilicon layer can be dispersed in the plane of the semiconductor substrate 30, and the same effect as that of the second modification described above can be obtained.

Which side in the vertical direction of the polysilicon layer is covered with the high hardness layer, and on which side the high hardness layer divided into a plurality of patterns is disposed can be freely determined.

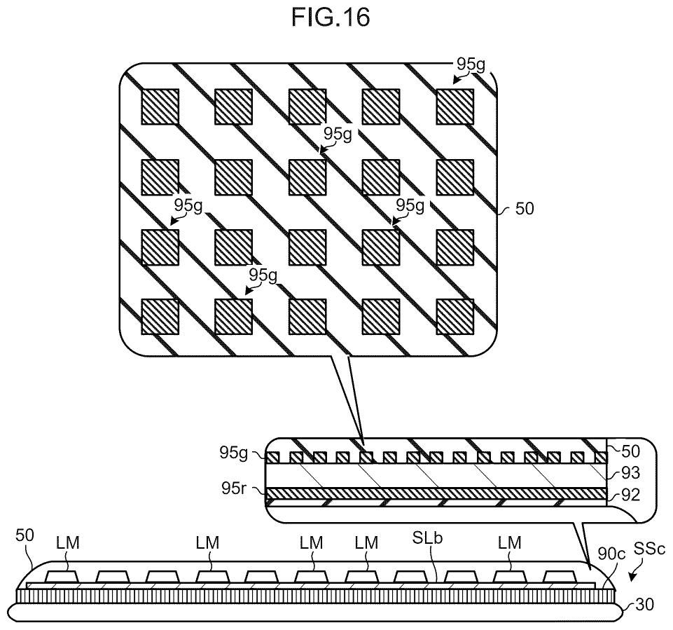

Next, a support substrate SSc of a third modification of the embodiment will be described with reference to FIGS. 16 to 18B. In the third modification, as an example, the support substrate SSc will be described in which an insulating layer 95g having high hardness, which is divided into a plurality of patterns, is disposed on the side of the polysilicon layer 93 facing the insulating layer 50, and the side of the polysilicon layer 93 facing the insulating layer 92 is covered with an insulating layer 95r having high hardness.

In the following drawings, the same reference numerals are given to the same configurations as those of the embodiment described above, and the description thereof may be omitted.

FIG. 16 is a cross-sectional view illustrating an example of a configuration of the support substrate SSc according to the third modification of the embodiment. As illustrated in FIG. 16, the support substrate SSc of the third modification has a configuration in which a multilayer structure 90c is formed on the semiconductor substrate 30. The multilayer structure 90c includes the insulating layer 92, the polysilicon layer 93, and the insulating layers 95g and 95r.

Here, the support substrate SSc may have the insulating layer 91 such as a silicon nitride layer covering both surfaces of the semiconductor substrate 30, similarly to the embodiment described above. That is, the multilayer structure 90c of the third modification may further include the insulating layer 91.

The insulating layers 95g and 95r are, for example, silicon nitride layers or the like, and have higher hardness than the insulating layer 92 such as a silicon oxide layer. More specifically, the insulating layers 95g and 95r preferably have a Young's modulus of, for example, twice or more, more preferably four times or more the Young's modulus of the insulating layer 92. As an example, the Young's modulus in a case where the insulating layers 95g and 95r are silicon nitride layers is 300 GPa, and the Young's modulus in a case where the insulating layer 92 is a silicon oxide layer is 73,1 GPa.

The insulating layer 95g is provided on the upper surface of the polysilicon layer 93, that is, the surface on the side facing the insulating layer 50, with a thickness of, for example, 20 nm or more and 300 nm or less. In addition, the insulating layer 95g is divided into a plurality of patterns when viewed from the stacking direction of the individual layers in the multilayer structure 90c. As a result, the insulating layer 95g protrudes from the upper surface of the polysilicon layer 93 and is buried in the insulating layer 92. A partial upper surface of the polysilicon layer 93 is in contact with the insulating layer 50.

The shape of each of the insulating layers 95g divided into the plurality of patterns is, for example, a rectangular shape when viewed from the stacking direction of the individual layers in the multilayer structure 90c. Here, the shape of the insulating layer 95g is not limited to a rectangular shape, and may be, for example, a polygon, a circle, an ellipse, or the like.

The size of the upper surface of each insulating layer 95g is, for example, 100 nm or more and 1000 nm or less. Here, the size of the upper surface of the insulating layer 95g can be determined as the maximum width in a case where the insulating layer 95g has a polygonal shape such as a rectangle, and as the maximum diameter in a case where the insulating layer 95g has a circular shape.

The insulating layers 95g divided into the plurality of patterns are dispersedly arranged in the insulating layer 50 in a grid shape, for example, when viewed from the stacking direction of the individual layers in the multilayer structure 90c. However, the arrangement of the insulating layers 95g is not limited to a grid shape, and the insulating layers 95g may be arranged in a zigzag shape or arranged radially or concentrically on the circular semiconductor substrate 30, for example.

When the pitch of the insulating layer 95g is defined as a distance connecting the center points of the upper surface shapes of the insulating layer 95g, the insulating layer 95g has a pitch of, for example, 100 nm or more and 1000 nm or less.

The insulating layer 95r is provided to have a thickness of, for example, 20 nm or more and 300 nm or less so as to cover the lower surface of the polysilicon layer 93, that is, the surface on the side facing the insulating layer 92.

The support substrate SSc described above can be manufactured as follows.

That is, the insulating layer 92, the insulating layer 95r, the polysilicon layer 93, and the insulating layer 95g, which is a blanket layer before patterns are formed, are formed in this order on the semiconductor substrate 30, and the insulating layer 95g is divided into a plurality of patterns by RIE or the like. Thereafter, the polysilicon layer 93 including the insulating layer 95g divided into the plurality of patterns is covered with a part of the insulating layer 50, so that the support substrate SSc described above is manufactured.

The insulating layers 95g and 95r do not need to be in close contact with the polysilicon layer 93. That is, the insulating layer 95g may be buried in the insulating layer 50 at a predetermined depth, and the insulating layer 95r may be buried in the insulating layer 92 at a predetermined depth. In this case, the insulating layer 50 or the insulating layer 92 can be formed in two stages while the insulating layer 95g or the insulating layer 95r is interposed.

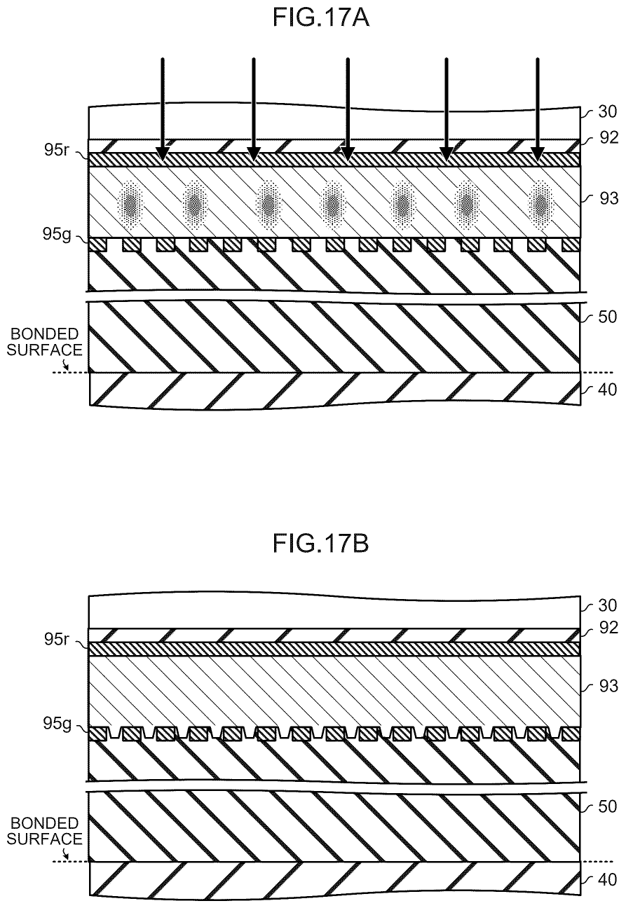

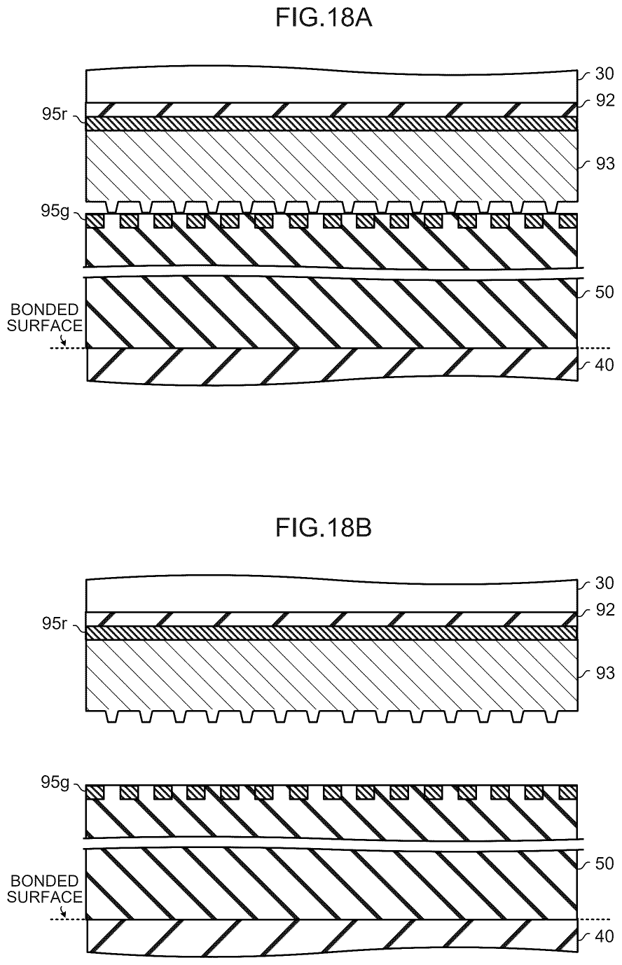

Next, a state where the support substrate SSc configured as described above is separated is illustrated in FIGS. 17A to 18B. FIGS. 17A to 18B are schematic cross-sectional views illustrating a state of separating of the support substrate SSc according to the third modification of the embodiment.

As illustrated in FIG. 17A, the support substrate SSc of the third modification and the semiconductor substrate SB on which the peripheral circuit CBA is formed are also bonded to each other by joining the insulating layer 50 including the pillar PL, the stacked body LM, and the like further stacked on the support substrate SSc and the insulating layer 40 covering the peripheral circuit CBA of the semiconductor substrate SB.

The bonded body of the support substrate SSc and the semiconductor substrate SB is irradiated with a laser beam having a wavelength of, for example, 9 μm or more and 10 μm or less from the support substrate SSc side. At this time, for example, it is preferable to use a carbon dioxide gas laser having a wavelength of 10.6 μm with a large spot diameter as in the second modification described above. In addition, a laser beam may be continuously emitted, or may be emitted in a pulsed manner. In a case where the laser beam is emitted in a pulsed manner, the pitch of the irradiation position of the laser beam can be set to, for example, 15 μm or less, more preferably 5 μm or less.

As a result, the polysilicon layer 93 generates heat, and the insulating layer 92 interposed between the polysilicon layer 93 and the semiconductor substrate 30 prevents or reduces heat from the polysilicon layer 93 from being transferred to the semiconductor substrate 30.

As illustrated in FIG. 17B, the polysilicon layer 93 that has generated heat by a laser beam is thermally expanded. At this time, the insulating layer 95r having high hardness covering the upper surface of the polysilicon layer 93 prevents or reduces the polysilicon layer 93 from expanding upward, that is, toward the insulating layer 92 and semiconductor substrate 30 side. In addition, the insulating layer 95g disposed on the lower surface of the polysilicon layer 93 and divided into a plurality of patterns prevents or reduces a part of the polysilicon layer 93 from expanding downward, that is, toward the insulating layer 50 side.

Here, in a portion where the insulating layer 95g is not disposed on the lower surface of the polysilicon layer 93, the polysilicon layer 93 expands downward. At this time, since thermal expansion to the upper side and partial thermal expansion to the lower side are inhibited, the amount of thermal expansion of the polysilicon layer 93 in the portion where the insulating layer 95g is not disposed increases.

As illustrated in FIG. 18A, the insulating layer 50 in direct contact with the lower surface of the polysilicon layer 93 is pushed down by the thermally expanded portion of the polysilicon layer 93, and cleavage occurs at the interface between the polysilicon layer 93 and the insulating layer 50.

As illustrated in FIG. 18B, due to the cleavage generated at the interface between the polysilicon layer 93 and the insulating layer 50, the support substrate SSc is separated in a manner that the polysilicon layer 93 is attached to the insulating layers 92 and 95r and semiconductor substrate 30 side.

According to the support substrate SSc of the third modification, the insulating layers 95g and 95r arranged respectively on the lower and upper surfaces of the polysilicon layer 93 are further provided, and the insulating layer 95g disposed on the surface of the polysilicon layer 93 facing the insulating layer 50 is divided into a plurality of patterns when viewed from the stacking direction of the insulating layer 92 and the polysilicon layer 93.

As a result, thermal expansion of the polysilicon layer 93 toward the insulating layer 92 side is prevented or reduced, and the amount of thermal expansion toward the insulating layer 50 side can be increased. Therefore, cleavage can be more easily generated at the interface between the polysilicon layer 93 and the insulating layer 50, and the separatability of the semiconductor substrate 30 can be improved. In addition, thermal expansion of the polysilicon layer 93 toward the insulating layer 92 side can be prevented or reduced, and stress applied to the semiconductor substrate 30 can be further reduced.

According to the support substrate SSc of the third modification, other effects similar to those of the support substrate SSb of the second modification are also obtained.

### Fourth Modification

In the third modification described above, the insulating layer 95g having high hardness, which is divided into a plurality of patterns, is disposed on the side of the polysilicon layer 93 in contact with the insulating layer 50, and the insulating layer 92 side of the polysilicon layer 93 is covered with the insulating layer 95r having high hardness. However, as described above, the arrangement of these insulating layers 95g and 95r on the polysilicon layer 93 may be reversed.

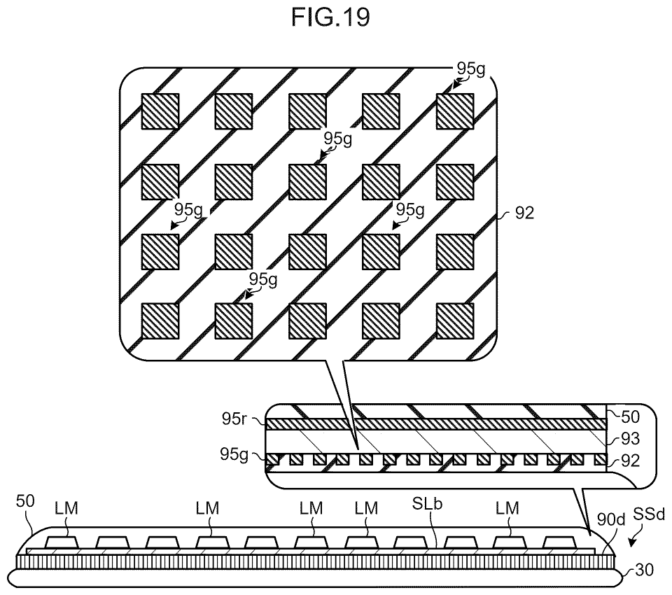

Next, a support substrate SSd of a fourth modification of the embodiment will be described with reference to FIGS. 19 to 21B. In the fourth modification, the support substrate SSd will be described in which the side of the polysilicon layer 93 facing the insulating layer 50 is covered with the insulating layer 95r having high hardness, and the insulating layer 95g having high hardness, which is divided into a plurality of patterns, is disposed on the side of the polysilicon layer 93 facing the insulating layer 92.

In the following drawings, the same reference numerals are given to the same configurations as those of the embodiment described above, and the description thereof may be omitted.

FIG. 19 is a cross-sectional view illustrating an example of a configuration of the support substrate SSd according to the fourth modification of the embodiment. As illustrated in FIG. 19, the support substrate SSd of the fourth modification has a configuration in which a multilayer structure 90d is formed on the semiconductor substrate 30. The multilayer structure 90d includes the insulating layer 92, the polysilicon layer 93, and the insulating layers 95g and 95r.

Here, the support substrate SSd may have the insulating layer 91 such as a silicon nitride layer covering both surfaces of the semiconductor substrate 30, similarly to the embodiment described above. That is, the multilayer structure 90d of the fourth modification may further include the insulating layer 91.

In the support substrate SSd of the fourth modification, the insulating layer 95g is divided into a plurality of patterns and disposed on the lower surface of the polysilicon layer 93, that is, the surface on the side facing the insulating layer 92.

On the other hand, the insulating layer 95r is provided so as to cover the upper surface of the polysilicon layer 93, that is, the surface on the side facing the insulating layer 50.

The support substrate SSd described above can also be manufactured in the same manner as the support substrate SSc of the third modification described above.

Also in the support substrate SSd of the fourth modification, the insulating layers 95g and 95r do not need to be in direct contact with the polysilicon layer 93, and may be buried in the insulating layer 92 and the insulating layer 50, respectively.

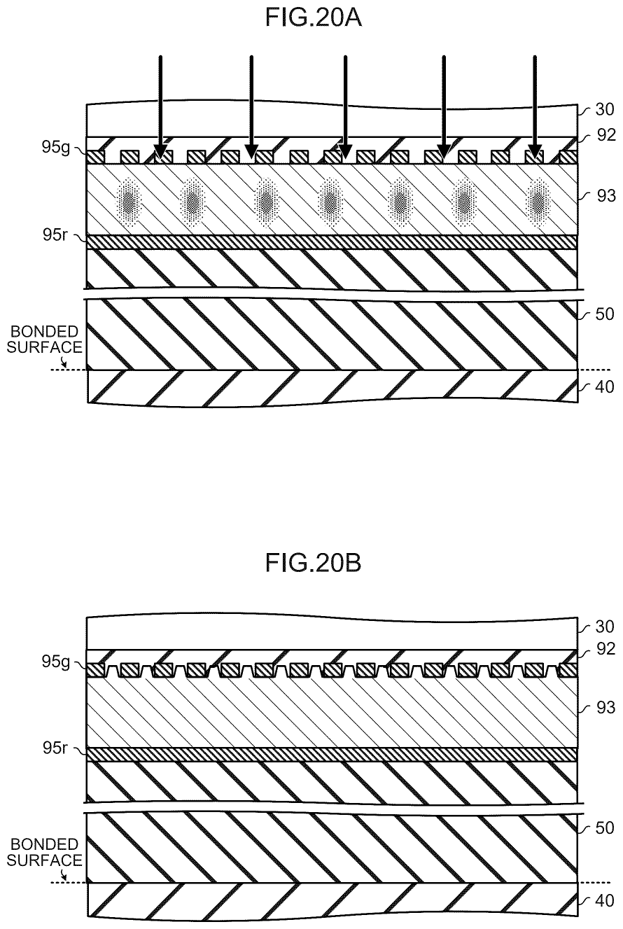

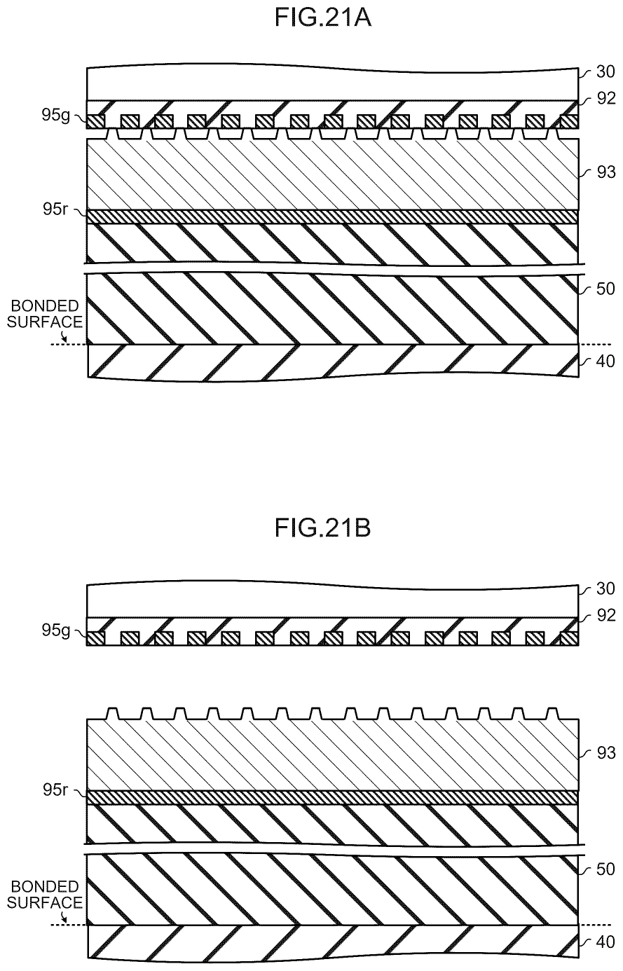

Next, a state where the support substrate SSd configured as described above is separated is illustrated in FIGS. 20A to 21B. FIGS. 20A to 21B are schematic cross-sectional views illustrating a state of separating of the support substrate SSd according to the fourth modification of the embodiment.

As illustrated in FIG. 20A, the support substrate SSd of the fourth modification and the semiconductor substrate SB on which the peripheral circuit CBA is formed are also bonded to each other by joining the insulating layer 50 formed on the support substrate SSd so as to include the pillar PL, the stacked body LM, and the like and the insulating layer 40 covering the peripheral circuit CBA of the semiconductor substrate SB.

The bonded body of the support substrate SSd and the semiconductor substrate SB is irradiated with a laser beam having a wavelength of, for example, 9 μm or more and 10 μm or less from the support substrate SSd side. At this time, for example, it is preferable to use a carbon dioxide gas laser having a wavelength of 10.6 μm with a large spot diameter as in the second and third modifications described above. In addition, a laser beam may be continuously emitted, or may be emitted in a pulsed manner. In a case where the laser beam is emitted in a pulsed manner, the pitch of the irradiation position of the laser beam can be set to, for example, 15 μm or less, more preferably 5 μm or less.

As a result, the polysilicon layer 93 generates heat, and the insulating layer 92 interposed between the polysilicon layer 93 and the semiconductor substrate 30 prevents or reduces heat from the polysilicon layer 93 from being transferred to the semiconductor substrate 30.

As illustrated in FIG. 20B, the polysilicon layer 93 that has generated heat by a laser beam is thermally expanded. At this time, the insulating layer 95r having high hardness covering the lower surface of the polysilicon layer 93 prevents or reduces the polysilicon layer 93 from expanding downward, that is, toward the insulating layer 50 side. In addition, the insulating layer 95g disposed on the upper surface of the polysilicon layer 93 and divided into a plurality of patterns prevents or reduces a part of the polysilicon layer 93 from expanding upward, that is, toward the insulating layer 92 and semiconductor substrate 30 side.

Here, in a portion where the insulating layer 95g is not disposed on the upper surface of the polysilicon layer 93, the polysilicon layer 93 expands upward. At this time, since thermal expansion to the lower side and partial thermal expansion to the upper side are inhibited, the amount of thermal expansion of the polysilicon layer 93 in the portion where the insulating layer 95g is not disposed increases.

As illustrated in FIG. 21A, the insulating layer 92 in direct contact with the upper surface of the polysilicon layer 93 is pushed up by the thermally expanded portion of the polysilicon layer 93, and cleavage occurs at the interface between the polysilicon layer 93 and the insulating layer 92.

As illustrated in FIG. 21B, due to the cleavage generated at the interface between the polysilicon layer 93 and the insulating layer 92, the support substrate SSd including the insulating layers 92 and 95r and the semiconductor substrate 30 is separated in a manner that the polysilicon layer 93 remains on the insulating layers 50 side.

According to the support substrate SSd of the fourth modification, the insulating layers 95g and 95r arranged respectively on the upper and lower surfaces of the polysilicon layer 93 are further provided, and the insulating layer 95g disposed on the surface of the polysilicon layer 93 facing the insulating layer 92 is divided into a plurality of patterns when viewed from the stacking direction of the insulating layer 92 and the polysilicon layer 93.

As a result, thermal expansion of the polysilicon layer 93 toward the insulating layer 50 side is prevented or reduced, and the amount of thermal expansion toward the insulating layer 92 side can be increased. Therefore, cleavage can be more easily generated at the interface between the polysilicon layer 93 and the insulating layer 92, and the separatability of the semiconductor substrate 30 can be improved. In addition, thermal expansion of the polysilicon layer 93 toward the insulating layer 50 side can be prevented or reduced, and stress applied to the device side including the pillar PL, the stacked body LM, and the like can be reduced.

According to the support substrate SSd of the fourth modification, other effects similar to those of the support substrate SSb of the second modification are also obtained.

As described in the third and fourth modifications, which of the insulating layers 95g and 95r is disposed on which side in the vertical direction of the polysilicon layer 93 can be determined by determining damage on which side in the vertical direction of the polysilicon layer 93 is desired to be further reduced in the configuration including the polysilicon layer 93 and the insulating layer 92, for example.

That is, although damage to the semiconductor substrate 30 is prevented or reduced to an allowable value or less by the configurations of the embodiment and the like described above including the polysilicon layer 93 and the insulating layer 92, in a case where it is desired to more reliably prevent or reduce the damage to the semiconductor substrate 30, by covering the surface of the polysilicon layer 93 facing the insulating layer 92 with the insulating layer 95r, it is possible to more reliably prevent or reduce thermal expansion of the polysilicon layer 93 toward the insulating layer 92 and semiconductor substrate 30 side.

On the other hand, on the premise that the damage to the semiconductor substrate 30 is sufficiently prevented or reduced by the configurations of the embodiment described above and the like including the polysilicon layer 93 and the insulating layer 92, for the purpose of preventing or reducing damage to the device side, the surface of the polysilicon layer 93 facing the insulating layer 50 can be covered with the insulating layer 95r to prevent or reduce thermal expansion of the polysilicon layer 93 to the insulating layer 50 side.

### Examples

Hereinafter, examples will be described in detail with reference to the drawings. In the example, a measurement method and a measurement result of absorptivity of light having each wavelength in a polysilicon layer functioning as a thermal expansion layer are shown.

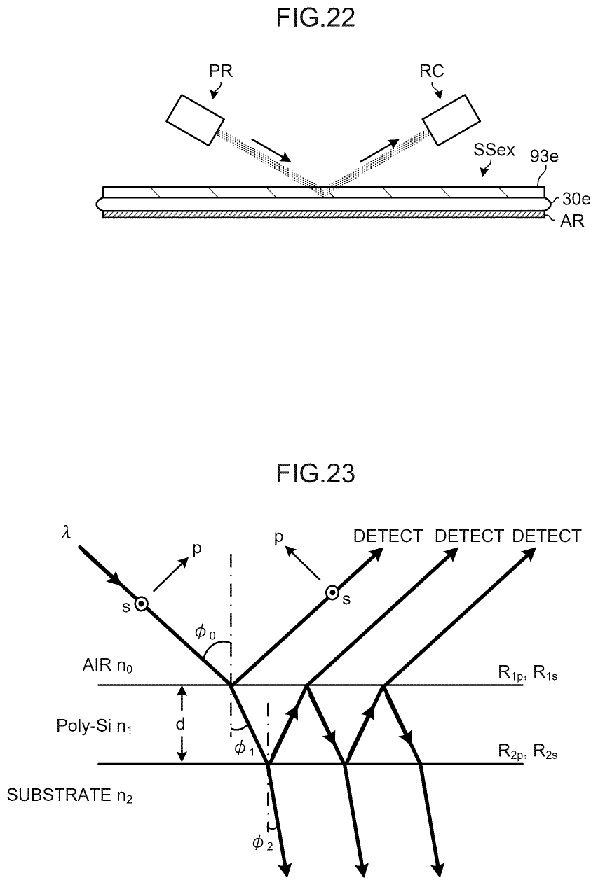

FIG. 22 is a schematic diagram illustrating a measurement substrate SSex according to the example and a method of measuring absorptivity.

As illustrated in FIG. 22, the measurement substrate SSex is a semiconductor substrate 30e in which an antireflection layer AR is formed on the back surface and a polysilicon layer 93e or the like as an absorptivity measurement target is formed on the front surface.

Light is obliquely incident on such a measurement substrate SSex from a light projector PR, and light reflected from a measurement target such as the polysilicon layer 93e is detected by a light receiver RC.

The wavelength of the light emitted from the light projector PR can be changed in a range of, for example, 3.0 μm to 12 μm. The light that is multiple-reflected by the upper surface, the lower surface, and the like of the polysilicon layer 93e and finally reflected toward the light receiver RC side is detected by the light receiver RC. At this time, by making light obliquely incident on the measurement substrate SSex, it is possible to decompose and detect light beams due to multiple reflection.

Such measurement can be performed using a spectroscopic ellipsometer or the like including the light projector PR and the light receiver RC.

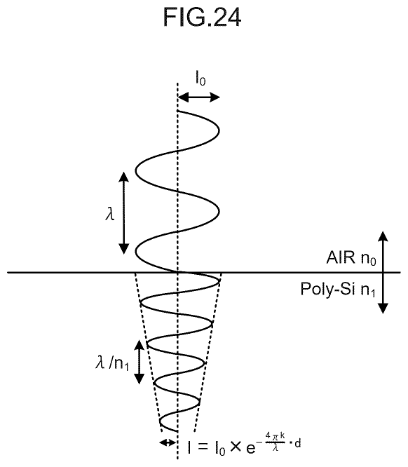

FIGS. 23 and 24 are schematic diagrams illustrating a method of calculating the absorptivity of the polysilicon layer 93e included in the measurement substrate SSex according to the example.

As illustrated in FIG. 23, light having a wavelength λ is obliquely incident on the measurement substrate SSex from the light projector PR. The incident angle at this time is assumed to be an angle φ₀ with respect to a perpendicular drawn on the upper surface of the polysilicon layer 93e on the measurement substrate SSex.

A part of the light reaching the polysilicon layer 93e from the light projector PR is reflected on the upper surface of the polysilicon layer 93e and detected by the light receiver RC. The incident light from the light projector PR and the reflected light from the polysilicon layer 93e each include a p-polarization component and an s-polarization component.

The p-polarization component is a polarization component parallel to the incident surface from the light projector PR, and the s-polarization component is a polarization component perpendicular to the incident surface of the light from the light projector PR. The light incident surface is a surface including both incident light from the light projector PR and reflected light from the polysilicon layer 93e. The p-polarization component and the s-polarization component affect the reflectance of the light having the wavelength λ in the polysilicon layer 93e.

Another part of the light reaching the polysilicon layer 93e from the light projector PR is incident on the polysilicon layer 93e at an angle φ₁ with respect to the layer thickness direction of the polysilicon layer 93e. A part of the light incident into the polysilicon layer 93e is reflected on the lower surface of the polysilicon layer 93e, and the other part is transmitted to the semiconductor substrate 30e side at an angle φ₂ with respect to the layer thickness direction of the polysilicon layer 93e.

A part of the light reflected on the lower surface of the polysilicon layer 93e is transmitted through the upper surface of the polysilicon layer 93e and detected by the light receiver RC. The other part of the light reflected on the lower surface of the polysilicon layer 93e is further reflected on the upper surface of the polysilicon layer 93e. A part of the light reflected on the upper surface of the polysilicon layer 93e is reflected on the lower surface of the polysilicon layer 93e, and the other part is transmitted to the semiconductor substrate 30e side.

As described above, the light reflected on the surface of the polysilicon layer 93e and the light multiple-reflected in the polysilicon layer 93e and finally transmitted to the light receiver RC side are detected by the light receiver RC. In addition, an n/k value is obtained using the following Formulas (1) to (8) on the basis of information related the light beams detected by the light receiver RC. n is a refractive index of the polysilicon layer 93e, and k is an extinction coefficient of the polysilicon layer 93e.

Intensity reflectance of p-polarization component Rp=rₚ·rₚ . . . (1)

Intensity reflectance of s-polarization component Rs=rₛ·rₛ . . . (2)

rₚ: amplitude reflectance of p-polarization component

rₛ: amplitude reflectance of s-polarization component

rₚ=(r₁ₚ+r₂ₚ×e^{-iδ})/(1+r₁ₚ·r₂ₚ×e^{-iδ}) (3)

rₛ=(r₁ₛ+r₂ₛ×e^{-iδ})/(1+r₁ₛ·r₂ₛ×e^{-iδ}) (4)

δ=(4π/λ)nd·cos φ₁ (5)
i: imaginary number
δ: phase difference when light having wavelength λ reciprocates once in polysilicon layer 93e
n: refractive index of polysilicon layer 93e
d: layer thickness of polysilicon layer 93e

Reflection Fresnel coefficient of p-polarization component rᵢₚ=(nᵢ·cos φᵢ₋₁−nᵢ₋₁·cos φᵢ)/(nᵢ·cos φᵢ₋₁+nᵢ₋₁·cos φᵢ) . . . (6)

Reflection Fresnel coefficient of s-polarization component rᵢₛ=(nᵢ₋₁·cos φᵢ−nᵢ·cos φᵢ₋₁)/(nᵢ₋₁·cos φᵢ+nᵢ·cos φᵢ₋₁) . . . (7)
nᵢ: complex refractive index of polysilicon layer 93e

n=nᵢ−ik (8)

Here, the refractive index and the layer thickness of the polysilicon layer 93e are known. Therefore, the n/k value is obtained by the above Formulas (1) to (8).

As illustrated in FIG. 24, in a case where the light having the wavelength λ is incident on the polysilicon layer 93e at the intensity I₀, in the polysilicon layer 93e, the wavelength of the light becomes a wavelength λ/n₁ based on a refractive index n₁ of the polysilicon layer 93e, and the intensity I of the light transmitted through the polysilicon layer 93e having the layer thickness d is expressed by the following Formula (9).

I=I₀×exp ((−4πk/λ)·d) (9)

In addition, the absorptivity A of the light having the wavelength λ in the polysilicon layer 93e can be obtained from the following Formula (10).

Absorptivity A=(I₀−I)/I₀=1−e^{αx} . . . (10)
α: absorption coefficient

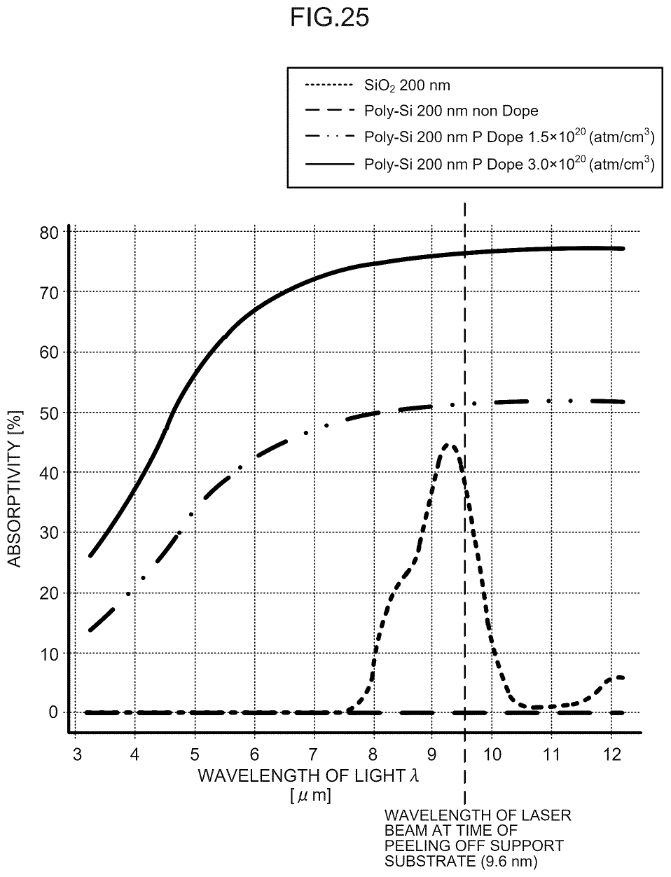

FIG. 25 is a graph showing the absorptivity of the polysilicon layer 93e included in the measurement substrate SSex according to the example. In the graph of FIG. 25, the horizontal axis represents the wavelength λ (nm) of the light emitted to the polysilicon layer 93e, and the vertical axis represents the absorptivity (%) of the light having each wavelength λ in the polysilicon layer 93e.

In addition, as the polysilicon layer 93e illustrated in FIG. 22, a non-doped polysilicon layer, a polysilicon layer doped with phosphorus of 1.5×10²⁰ atom/cm³, and a polysilicon layer doped with phosphorus of 3.0×10²⁰ atom/cm³ were used as measurement targets. The thickness of these polysilicon layers was 200 nm. For comparison, the absorptivity of the silicon oxide layer used for the insulating layer 92 and the like and having a layer thickness of 200 nm was also measured.

In the graph of FIG. 25, for reference, 9.6 μm, which is the wavelength of a carbon dioxide gas laser beam that can be used at the time of separating the support substrate SS of the embodiment described above, is indicated by a broken line.

As illustrated in FIG. 25, the absorptivity of light in the silicon oxide layer having a layer thickness of 200 nm was about 45% at a wavelength λ of about 9 μm, and the absorptivity of light in the non-doped polysilicon layer 93e was consistently 0% over a wavelength of 3.0 μm to 12 μm.

On the other hand, the result showed that the absorptivity in the phosphorus-doped polysilicon layer 93e increased as the wavelength λ of light increased up to around a wavelength of 7.0 μm, and the amount of increase in absorptivity also was larger as the phosphorus concentration was higher.

More specifically, in the polysilicon layer doped with phosphorus of 3.0×10²⁰ atom/cm³, the absorptivity at a wavelength λ of 9 μm or more was 75% or more, and in the polysilicon layer doped with phosphorus of 1.5×10²⁰ atom/cm³, the absorptivity was 50% or more.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A stacked substrate for separating a semiconductor substrate using thermal expansion by a laser beam, the stacked substrate comprising:
the semiconductor substrate;
a first insulating layer disposed above the semiconductor substrate; and
a polysilicon layer that is disposed in contact with the first insulating layer, a thickness of the polysilicon layer being larger than a thickness of the first insulating layer in a direction perpendicular to a surface of the semiconductor substrate, and the polysilicon layer being doped with phosphorus.

2. The stacked substrate according to claim 1, wherein
the polysilicon layer has a phosphorus concentration of 1.5×10²⁰ atom/cm³ or more.

3. The stacked substrate according to claim 1, wherein
in the polysilicon layer, absorptivity of light having a wavelength of 9 μm or more and 10 μm or less is 50% or less.

4. The stacked substrate according to claim 1, wherein
a thermal conductivity of the polysilicon layer is 10 times or more higher than a thermal conductivity of the first insulating layer.

5. The stacked substrate according to claim 4, wherein
the first insulating layer is a silicon oxide layer.

6. The stacked substrate according to claim 1, wherein
the polysilicon layer is divided into a plurality of patterns when viewed from the direction.

7. The stacked substrate according to claim 6, wherein
the first insulating layer is also disposed between the plurality of patterns of the polysilicon layer.

8. The stacked substrate according to claim 1, further comprising
a metal layer disposed above the polysilicon layer.

9. The stacked substrate according to claim 1, further comprising
a second insulating layer between the semiconductor substrate and the first insulating layer, wherein
the first insulating layer is an oxide layer, and
the second insulating layer is a nitride layer.

10. The stacked substrate according to claim 1, further comprising
first and second nitride layers arranged on upper and lower surfaces of the polysilicon layer, wherein
one of the first and second nitride layers is divided into a plurality of patterns when viewed from the direction.

11. The stacked substrate according to claim 1, further comprising
a device layer including a part of a semiconductor device above the polysilicon layer.

12. The stacked substrate according to claim 11, wherein
a thickness of the first insulating layer between the semiconductor substrate and the polysilicon layer is 20 nm or more and 50 nm or less,
the thickness of the polysilicon layer is 100 nm or more and 300 nm or less, and
a thickness of the device layer is 500 nm or more.

13. A method of manufacturing a semiconductor device, comprising:
forming a first insulating layer and a polysilicon layer doped with phosphorus in this order above a first semiconductor substrate;
forming a device layer including a part of a semiconductor device above the polysilicon layer; and
irradiating the polysilicon layer with a laser beam to generate cleavage between the first insulating layer and the polysilicon layer, and separating the first semiconductor substrate.

14. The method of manufacturing a semiconductor device according to claim 13, wherein
the forming the device layer includes
forming, above the polysilicon layer, a stacked body in which a plurality of conductive layers are stacked apart from each other, the stacked body including a memory pillar penetrating the plurality of conductive layers.

15. The method of manufacturing a semiconductor device according to claim 14, further comprising:
before separating the first semiconductor substrate,
forming a peripheral circuit including a transistor on a second semiconductor substrate; and
bonding a surface of the first semiconductor substrate on which the device layer is formed and a surface of the second semiconductor substrate on which the peripheral circuit is formed.

16. The method of manufacturing a semiconductor device according to claim 13, wherein
the forming the polysilicon layer includes
doping the polysilicon layer with phosphorus having a concentration of 1.5×10²⁰ atom/cm³ or more.

17. The method of manufacturing a semiconductor device according to claim 13, wherein
the forming the polysilicon layer includes
forming a plurality of recess patterns in the first insulating layer, and
filling the plurality of recess patterns with the polysilicon layer.

18. The method of manufacturing a semiconductor device according to claim 13, further comprising
forming a metal layer above the polysilicon layer.

19. The method of manufacturing a semiconductor device according to claim 13, further comprising
forming first and second nitride layers arranged on upper and lower surfaces of the polysilicon layer, wherein
the forming the first and second nitride layers includes
dividing one of the first and second nitride layers into a plurality of patterns when viewed from a stacking direction of the first insulating layer and the polysilicon layer.

20. The method of manufacturing a semiconductor device according to claim 13, further comprising
before forming the first insulating layer, forming a second insulating layer above the first semiconductor substrate, wherein
the first insulating layer is an oxide layer, and
the second insulating layer is a nitride layer.
